(19) United States
(12) Patent Application Publication
(10) Pub. No.: US 2019/0286963 A1
(43) Pub. Date: Sep. 19, 2019

(54) ULTRA-HIGH FREQUENCY ANTENNA TAG

(71) Applicant: 3M INNOVATIVE PROPERTIES COMPANY, St. Paul, MN (US)

(72) Inventors: Mohsen Salehi, Woodbury, MN (US); Benjamin Münstermann, Duisburg (DE); Zohaib Hameed, Woodbury, MN (US)

(21) Appl. No.: 16/271,028

(22) Filed: Feb. 8, 2019

Related U.S. Application Data
(60) Provisional application No. 62/642,063, filed on Mar. 13, 2018.

(51) Int. Cl. G06K 19/077; G06K 19/07; H03H 7/38; F01D 5/12; F03D 80/00; G01R 27/26; H01Q 1/22; H01Q 1/38

(52) U.S. Cl. CPC G06K 19/07749; G06K 19/0726; H03H 7/38; F01D 5/12; F05D 2270/80; G01R 27/2605; H01Q 1/2208; H01Q 1/38; F05B 2270/80; F03D 80/00

(57) ABSTRACT

Ultra-high frequency (UHF) antenna tags are described. The antenna tag includes a sensor portion including terminals for attaching a chip and an antenna portion including first and second elements electrically connected to the sensor portion. At least one of the first and second elements includes at least one meandered portion. The sensor portion is responsive to a presence of a dielectric or magnetic material. The antenna tag is configured such that the antenna tag has an input impedance at the terminals substantially matched to a chip impedance. In some embodiments, the antenna tag has a directivity of at least 4 dBi in a predetermined direction and a radiation efficiency of at least 60 percent.

### BACKGROUND

U.S. Pat. No. 5,942,991 (Gaudreau) describes an apparatus and a related method for remotely measuring at least one environmental condition including an electromagnetically resonant sensor having a measurable resonance characteristic which varies in correspondence to changes in the environmental condition present at the sensor.

U.S. Pat. Appl. Publ. No. 2007/0159346 (Wesselink) describes transponder technology incorporated into the blades of a wind turbine to make it possible to transfer data wirelessly from each blade to the associated tower. By providing a transponder including a radio frequency identification (RFID) device in or on each of the blades and providing a reader/receiver in or on the tower support of the wind turbine, the reader/receiver can detect the operative RFID devices and/or read data from the RFID devices as the blades pass the tower.

U.S. Pat. Appl. Publ. No. 2016/0267769 (Rokhsaz et al.) describes an RFID moisture sensor. This moisture sensor includes one or more antenna structures having a tail. The tail is operable to transport a disturbance such as fluid or moisture from a monitored location where the antenna has an impedance and varies with proximity to the disturbance. An integrated circuit couples to the antenna structure. This IC includes a power harvesting module operable to energize the integrated circuit, an impedance matching engine coupled to the antenna, a memory module, and a wireless communication module. The impedance matching engine may vary a reactive component to reduce a mismatch between the antenna impedance and the IC and produce an impedance value (sensor code) representative of the reactive component impedance. The memory module stores the impedance value (sensor code) until the wireless communication module communicates with an RFID reader and sends the impedance value/sensor code to the RFID reader. The RFID reader may then determine an environmental condition such as the presence of moisture or fluids at the tail of the RFID sensor.

### SUMMARY

In some aspects of the present description, an ultra-high frequency (UHF) antenna tag including a sensor portion and an antenna portion is provided. The sensor portion includes terminals for attaching a chip having a chip impedance. The sensor portion is responsive to a presence of a dielectric or magnetic material proximate the sensor portion. The antenna portion includes first and second elements electrically connected to the sensor portion, where at least one of the first and second elements includes at least one meandered portion. The antenna tag is configured such that at a predetermined UHF frequency the antenna tag has an input impedance at the terminals substantially matched to the chip impedance, the antenna tag has a directivity of at least 4 dBi in a predetermined direction, and the antenna tag has a radiation efficiency of at least 60 percent.

In some aspects of the present description, an ultra-high frequency (UHF) antenna tag including a sensor portion and an antenna portion is provided. The sensor portion includes terminals for attaching a chip having a chip impedance. The sensor portion is responsive to a presence of a dielectric or magnetic material proximate the sensor portion. The antenna portion includes first and second meandered loop elements disposed on opposite sides of the sensor portion and electrically connected to the sensor portion such that the first meandered loop element and the sensor portion defines a first electrically closed loop and the second meandered loop element and the sensor portion defines a second electrically closed loop. The antenna tag is configured such that at a predetermined UHF frequency: the antenna tag has an input impedance at the terminals substantially matched to the chip impedance; the antenna tag has a radiation efficiency of at least 60 percent; and for an effective isotropic radiated power (EIRP) of 36 dBm, the UHF antenna tag has a maximum read range of at least 6 m.

In some aspects of the present description, an ultra-high frequency (UHF) antenna tag configured to be disposed on and conform to a curved surface is provided. The UHF antenna tag includes a sensor portion and an antenna portion. The sensor portion includes terminals for attaching a chip having an impedance. The sensor portion responsive to a presence a dielectric or magnetic material proximate the sensor portion. The antenna portion includes a first dipole portion disposed closer to the sensor portion and a second dipole portion disposed farther from the sensor portion, where the first and second dipole portions are electrically connected to the sensor portion. The antenna tag is configured such that at a predetermined UHF frequency when the antenna tag is disposed on and conforms to the curved surface: the antenna tag has an input impedance at the terminals substantially matched to the impedance of the chip; the antenna tag has a directivity of at least 3 dBi in a predetermined direction; and the antenna tag has a radiation efficiency of at least 45 percent.

In some aspects of the present description, a wind turbine including one or more rotor blades where each rotor blade includes a leading edge and where for at least one rotor blade, at least one ultra-high frequency (UHF) antenna tag is disposed on and conforms to a curved major surface of the rotor blade is provided. Each antenna tag includes a sensor portion and an antenna portion. The sensor portion is disposed on the leading edge of the rotor blade and is responsive to a presence a dielectric or magnetic material proximate the sensor portion. The sensor portion includes terminals and a chip is electrically connected to the terminals. The antenna portion includes a first dipole portion disposed closer to the sensor portion and a second dipole portion disposed farther from the sensor portion. The first and second dipole portions are electrically connected to the sensor portion. A first conductor length separates the first dipole portion from the sensor portion, and a second conductor length separates the second dipole portion from the sensor portion. The wind turbine further includes one or more reader antennas disposed proximate the at least one antenna tag. For each antenna tag and a reader antenna in the one or more reader antennas disposed to communicate with the antenna tag, a difference between the second and first conductor lengths is selected such that when the antenna tag is closest to the reader antenna, the antenna tag has a directivity of at least 3 dBi in a direction toward the reader antenna.

### BRIEF DESCRIPTION OF THE DRAWINGS

FIGS. 1-2 are top views of an antenna tag;

FIG. 3 is a top view of the sensor portion of the antenna tag of FIGS. 1-2;

FIGS. 4-5 are top views of another antenna tag;

FIG. 6 is a top view of a portion of the sensor portion of the antenna tag of FIGS. 4-5;

FIG. 7 is a schematic side view of an antenna tag;

FIG. 8 is a perspective cross-sectional view of a portion of a rotor blade where an antenna tag is disposed on and conforms to a curved surface of the rotor blade;

FIG. 9 is a schematic cross-sectional view of an antenna tag in a cross-section perpendicular to a length of the antenna tag;

FIG. 10A is a schematic front view of a wind turbine;

FIG. 10B is a perspective view of a region of a rotor of the wind turbined of FIG. 10A;

FIG. 10C is a perspective view of a portion of the region of FIG. 10B near an antenna tag showing a radiation pattern produced by the antenna tag;

FIGS. 11-12 are schematic top views of circuits to adjust a phase difference between first and second dipole portions of an antenna tag;

FIG. 13A is a schematic illustration of an impedance matching model;

FIG. 13B is an illustration of a shift of digitized sensor information due to a shift in impedance provided by a reactance autotuning integrated circuit;

FIG. 14 is a polar plot of the far-field directivity of the antenna tag of FIGS. 1-2;

FIG. 15 is a graph of the imaginary part of an input impedance of the antenna tag of FIGS. 1-2 versus frequency;

FIG. 16 is a graph of the real part of the input impedance of the antenna tag of FIGS. 1-2 versus frequency;

FIG. 17 is a graph of the return loss of the antenna tag of FIGS. 1-2 versus frequency;

FIG. 18 is a graph of the radiation efficiency of the antenna tag of FIGS. 1-2 versus frequency;

FIG. 19 is a graph of the transmitted power versus distance for the antenna tag of FIGS. 1-2 and for a comparative antenna tag;

FIG. 20 is a polar plot of the far-field directivity of the antenna tag of FIGS. 4-5 when disposed in a plane;

FIG. 21 is a polar plot of the far-field directivity of the antenna tag of FIGS. 4-5 when curved;

FIG. 22 is a graph of the imaginary part of an input impedance of the antenna tag of FIGS. 4-5 when disposed in a plane versus frequency;

FIG. 23 is a graph of the real part of the input impedance of the antenna tag of FIGS. 4-5 when disposed in a plane versus frequency;

FIG. 24 is a graph of the radiation efficiency of the antenna tag of FIGS. 4-5 when disposed in a plane versus frequency;

FIG. 25 is a graph of the imaginary part of an input impedance of the antenna tag of FIGS. 4-5 when curved versus frequency;

FIG. 26 is a graph of the real part of the input impedance of the antenna tag of FIGS. 4-5 when curved versus frequency;

FIG. 27 is a graph of the return loss of the antenna tag of FIGS. 4-5 when curved versus frequency; and

FIG. 28 is a graph of the radiation efficiency of the antenna tag of FIGS. 4-5 when curved versus frequency.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

For many applications, installations or devices, it is desired to monitor surfaces subject to physical or environmental exposure. Physical and/or environmental exposure may lead to significant changes of structural properties as well as of other significant physical properties of component(s) of applications, installations or devices. This may be exemplified by a wing of an aircraft and a blade of a wind turbine.

The formation of cracks in a wing of an aircraft can be a significant and immediate safety concern. Similarly, the formation of ice on a wing of an aircraft may not only lead to a blockage of important steering devices such as flaps, but also to a significant deterioration of aerodynamic properties such as a drop of lift the wing provides. Both can represent immediate safety risks. In particular, the formation of ice on aircraft wings was recognized as safety risk in the early pioneering age of motorized flight, and various counter-measures have been developed since, e.g. the spraying of anti-icing liquids and the provision of heating installations within wings. Thus, the observation of damages and/or the formation of ice on the surface of a wing is important during the operation of an aircraft in order to be able to initiate appropriate countermeasures.

The formation of ice on rotor blades of a wind turbine may lead to an increase of vibration and a decrease in lift, which decreases the rotation speed and therefore the power output of the turbine. Generally, the formation of ice on the surface of rotor blades of a wind turbine (also known as “icing”) may give rise to problems such as partial or complete loss of power production, reduction of power output due to altered or even disrupted aerodynamics, overloading caused by delayed stall, increased fatigue of components due to imbalance caused by the ice load, and/or damage or harm caused by uncontrolled shedding of large chunks of ice. Therefore, the formation of ice, cracks, or even accumulation of insects on the surface of the wings of a wind turbine trigger both economical and potential safety considerations.

Moreover, the monitoring of surfaces of blades of wind turbines face further challenges in that the blades consistently move, exhibit a large area. Furthermore, wind turbines are often installed in large numbers in remote areas such as in off-shore installations. Accordingly, visual inspections can be difficult, and due to economic considerations, computer-aided electronic solutions are desirable. Methods for monitoring the surface of a device, in particular the surface of a blade of a wind turbine, to physical and/or environmental exposure are described in international application number PCT/US2017/051065.

According to some embodiments of the present description, ultra-high frequency (UHF) antenna tags are provided which are useful in detecting the presence of water or ice and/or useful in detecting whether erosion has occurred. It is preferred that the antenna tag is a passively operating device. Using a passively operating antenna tag has the advantage that no means for providing electric energy such as batteries or wiring needs to be present in the tag. This has further advantages such as less complexity of the system, the system being less prone to damages or malfunctions, and a generally lighter and more compact antenna tag. An antenna tag typically includes an antenna disposed on a substrate than can be attached to article such as a wind turbine rotor blade. When a chip including a radio frequency identification (RFID) unit (e.g., which identifies the state of the chip) is attached to an antenna tag, the antenna tag may be referred to as an RFID tag.

The antenna tags of the present description typically include a sensor portion and an antenna portion where the sensor portion includes terminals for attaching a chip having a chip impedance Z_{Chip} which includes contributions from a chip reactance X_{Chip} (imaginary part of Z_{Chip}) and a chip resistance R_{Chip} (real part of Z_{Chip}). The antenna tag has an input impedance at the terminals Z_{A} which includes contributions from an input reactance X_{A} (imaginary part of Z_{A}) and an input resistance R_{A} (real part of Z_{A}). It is preferred that the input impedance Z_{A} is substantially matched to the chip impedance Z_{Chip} at least when no water or ice buildup is present on the antenna tag and when no erosion to any outer layer of the antenna tag has occurred so that there is efficient power transfer between the chip and the antenna. The input impedance Z_{A} is matched to the chip impedance Z_{Chip} when Z_{A} is equal to the complex conjugate of Z_{Chip}. It is generally not necessary for the input impedance of the antenna tag to be exactly matched to the chip impedance. In preferred embodiments, the input impedance of the antenna tag is sufficiently closely matched to the chip impedance that a return loss at the terminals is low. As used herein, an antenna tag has an input impedance at the terminals substantially matched to a chip impedance if a return loss at the terminals is no more than −6 dB. In some embodiments, at a predetermined UHF frequency, the return loss at the terminals is less than −6 dB, or preferably less than −8 dB, or more preferably less than −10 dB. The return loss may be in any of these ranges when the antenna tag is disposed in a plane and/or when the antenna tag is disposed on and conforms to a curved surface (e.g., a curved surface of a rotor blade).

In some embodiments, water or ice buildup (or buildup of other dielectric materials or of magnetic materials) on the antenna tag shifts the input impedance Z_{A} and the chip includes adaptive circuitry that shifts the chip impedance Z_{A} so that the input impedance Z_{A} is substantially matched to the chip impedance Z_{Chip} when water and/or ice buildup is present on the antenna tag. Similarly, in some embodiments, erosion to an outer layer (e.g., coating) of the antenna tag shifts the input impedance Z_{A} and the chip includes adaptive circuitry that shifts the chip impedance Z_{A} so that the input impedance Z_{A} is substantially matched to the chip impedance Z_{Chip} after erosion has taken place. In some embodiments, the adaptive circuitry autotunes the reactance of the chip to be in some range of reactance. In some embodiments, an input reactance at the terminals is a negative of a reactance in the range of reactance defined by the chip at least when there is no ice or water present and no erosion has occurred.

In some embodiments, an antenna is designed by using a T-matching technique in combination with meandered elements to provide an efficient and high gain antenna with a high read range. In wind turbine applications, a read range of at least 6 m is typically desired for an output power of a reader system at or below a specified limit. A read range of at least 7 m, or 7.5 m, or 8 m is often preferred. Typical rotor blade materials utilize composite material which have losses at the UHF frequencies of interest. This often results in reduced read ranges for conventional RFID antennas. In some embodiments, antennas tags of the present description can have a read range higher than conventional antenna tags due, at least in part, to a high directivity and/or efficiency. In some embodiments, the read range of the antenna tag when disposed on a rotor blade is at least 6 m, or at least 7 m, or at least 7.5 m, or at least 8 m at a specified reader output limit.

In some embodiments, the antenna tag has a radiation efficiency at a predetermined UHF frequency of at least 45 percent, or preferably at least 50 percent, or more preferably at least 55 percent, or even more preferably at least 60 percent. The radiation efficiency may be in any of these ranges when the antenna tag is disposed in a plane and/or when the antenna tag is disposed on and conforms to a curved surface (e.g., a curved surface of a rotor blade or a curved surface of an airplane wing). In some embodiments, a system (e.g., wind turbine) including at least one reader and at least one UHF antenna tag is provided and the predetermined UHF frequency is an operating frequency of the system. The ultra-high frequency (UHF) band is defined by the International Telecommunications Union (ITO) as the frequency band from 300 MHz to 3000 MHz. In some embodiments, the predetermined UHF frequency is in a range of from 700 to 1500 MHz, or preferably in a range of from 850 to 950 MHz, or more preferably in a range of from 865 to 928 MHz. For example, in some embodiments, the predetermined UHF frequency is in the industrial, scientific and medical (ISM) band from 902 MHz to 928 MHz (e.g., 915 MHz). Frequency dependent quantities can be understood to be evaluated at the predetermined UHF frequency unless specified differently or unless the context clearly indicates differently.

In some embodiments, the antenna tag is configured to radiate relatively strongly in a predetermined direction which is typically along or close to a direction from the antenna tag to a reader antenna. The antenna tag preferably has a largest directivity greater than that of an ideal half-wave dipole antenna (2.15 dBi). In some embodiments, the antenna tag has a directivity of at least 3 dBi, or at least 4 dBi, or at least 4.5 dBi, or at least 5 dBi in the predetermined direction at the predetermined UHF frequency. The directivity may be up to 8 dBi, or up to 6 dBi, for example. The directivity may be in any of these ranges when the antenna tag is disposed in a plane and/or when the antenna tag is disposed on and conforms to a curved surface (e.g., a curved surface of a rotor blade).

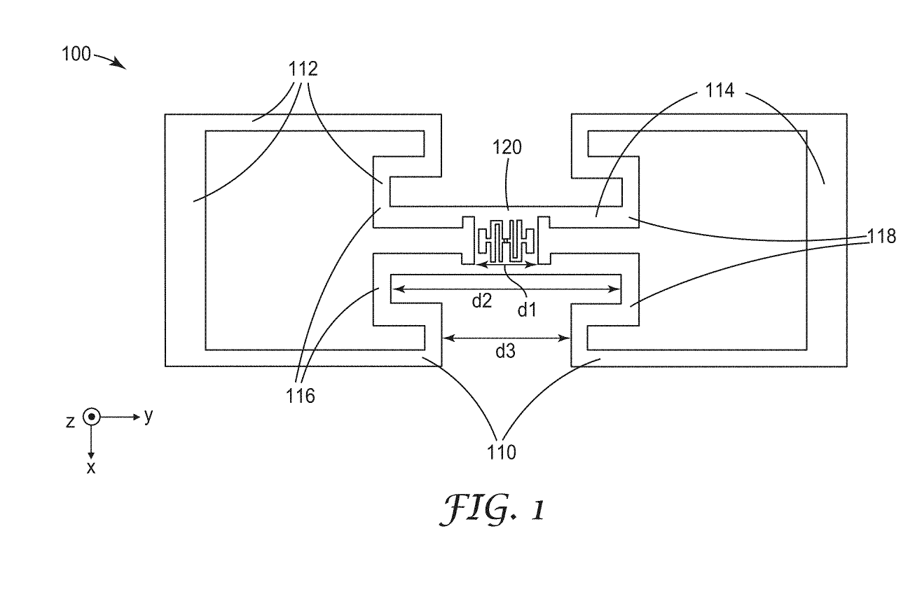

FIG. 1 is a top view of an antenna tag 100 including an antenna portion 110 and a sensor portion 120. The antenna portion includes first and second elements 112 and 114 electrically connected to the sensor portion 120. The first and second elements 112 and 114 are symmetrically disposed on opposing sides of the sensor portion 120. The first element 112 includes meandered portions 116 and the second element 114 includes meandered portions 118. In the illustrated embodiment, each of the first and second elements 112 and 114 includes two meandered portions (one having the shape of the number two and the other having the shape of a number five). More generally, an antenna portion may include first and second elements electrically connected to a sensor portion where at least one of the first and second elements includes at least one meandered portion. The antenna tag 100 may be made from a metal layer on a substrate as described further elsewhere herein.

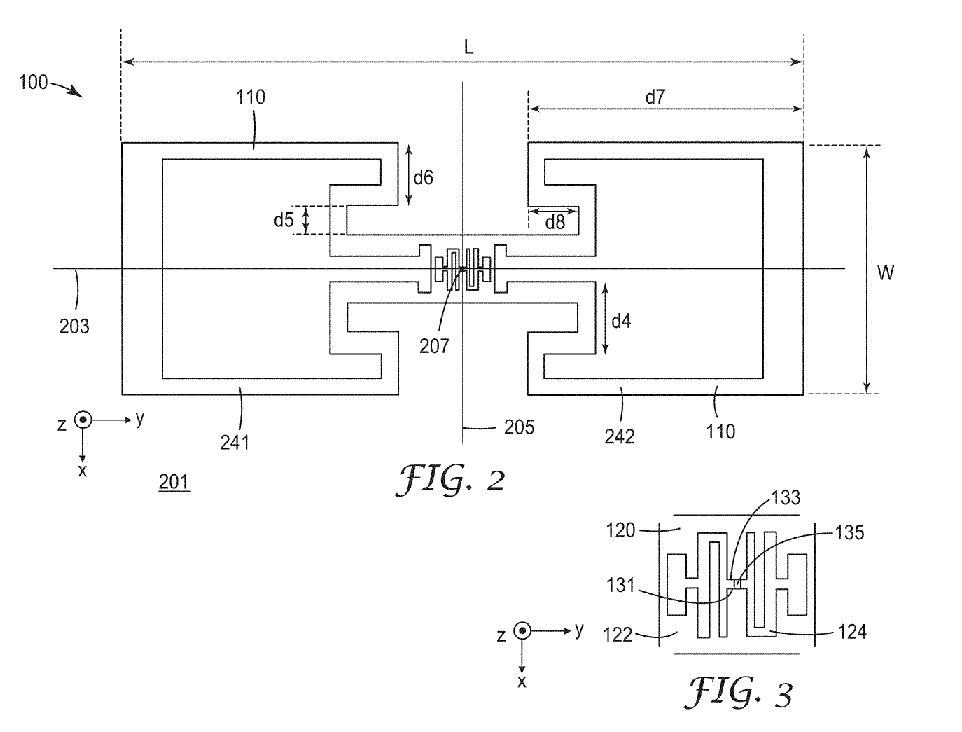

FIG. 2 is a top view of the antenna tag 100 disposed in a first plane 201 (the x-y plane referring to the x-y-z coordinate system depicted in FIGS. 1-3). Second plane 203 is orthogonal to the first plane 201 and third plane 205 is orthogonal to the first and second planes 201 and 203. An axis 207 (parallel to z-axis) which is perpendicular to the first plane 201 is indicated. In the illustrated embodiment, axis 207 is the intersection of the second and third planes 203 and 205. The antenna portion 110 is symmetric under reflection about the second plane 203 and symmetric under reflection about third plane 205.

In the illustrated embodiment, the first and second elements 112 and 114 are first and second meandered loop elements disposed on opposite sides of the sensor portion 120 and electrically connected to the sensor portion 120 such that the first meandered loop element and the sensor portion defines a first electrically closed loop 241 and the second meandered loop element and the sensor portion defines a second electrically closed loop 242. In other embodiments, the first and second elements of the antenna portion do not form electrically closed loops, as described further elsewhere herein.

The antenna tag 100 has a length L and a width W where L>W. In some embodiments, the length L is in a range of 0.5 to 0.8, or 0.55 to 0.73, or 0.55 to 0.69 times a predetermined wavelength where the predetermined wavelength is the speed of light in vacuum divided by the predetermined UHF frequency. In some embodiments, the width W is in a range of 0.2 to 0.7 or 0.3 to 0.5 times the length L. Dimensions d1, d2, and d3 are illustrated in FIG. 1 and dimensions d4, d5, d6, d7 and d8 are illustrated in FIG. 2. In some embodiments, d1 is in a range of 0.08 to 0.12 times L, d2 is in a range of 0.025 to 0.04 times L, and d3 is in a range of 0.15 to 0.25 times L, d4 is in a range of 0.08 to 0.12 times L, d5 is in a range of 0.03 to 0.05 times L, d6 is in a range of 0.07 to 0.11 times L, d7 is in a range of 0.3 to 0.5 times L, and d8 is in a range of 0.06 to 0.09. In some embodiments, L is in a range of 160 to 250 mm, or 180 mm to 220 mm. In some embodiments, the conductor length between opposite sides of the antenna in the length direction of the antenna is in a range of 0.9 to 1.1 times the predetermined wavelength. In the illustrated embodiment, this conductor length is d2+2(d5+d6+d7+d8). Utilizing meandering lines allow the conductor length to be approximately the predetermined wavelength while the length L is significantly smaller than the predetermined wavelength.

FIG. 3 is a top view of the sensor portion 120 of the antenna tag 100. The sensor portion 120 includes terminals 131 and 133 for attaching a chip 135. The sensor portion 120 includes a patterned conductor 122 which defines a gap pattern 124 in the patterned conductor 122. In some embodiments, when the antenna tag is disposed in the first plane 201, the gap pattern is symmetric under rotations of 180 degrees about the axis 207, which passes through the center of the chip 135.

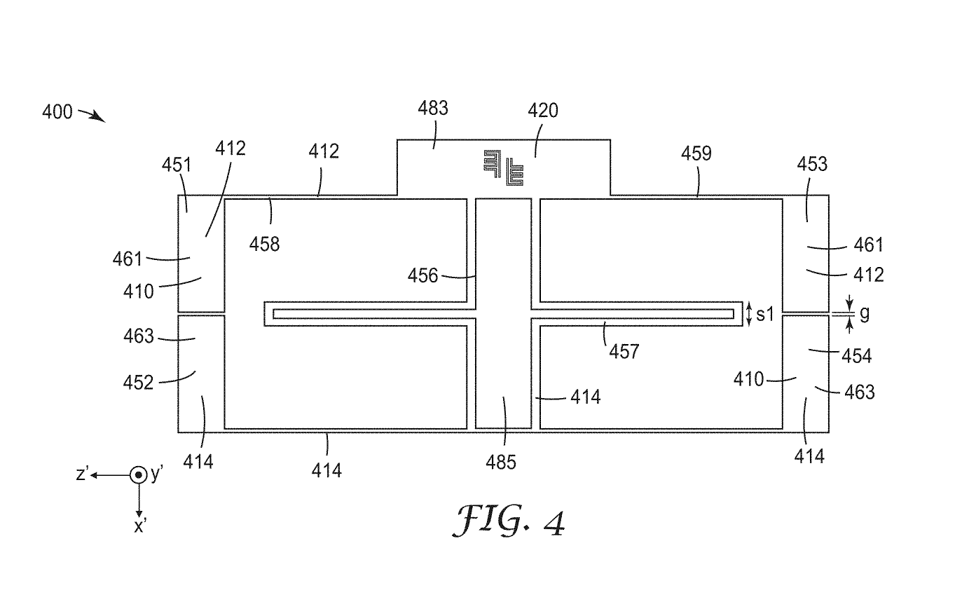

FIG. 4 is a top view of an antenna tag 400 including an antenna portion 410 and a sensor portion 420. The antenna portion 410 includes first and second elements 412 and 414 electrically connected to the sensor portion 420. The first element 412 is disposed closer to the sensor portion 420 and the second element 414 is disposed farther from the sensor portion 420 (a center of mass of the second element 414 is farther from a center of mass of the sensor portion 420 than a center of mass of the first element 412). The first element 412 includes first and second portions 451 and 453 and first and second linear connecting lines 458 and 459 electrically connecting the respective first and second portions 451 and 453 of the first element 412 to the sensor portion 420. The second element 414 includes first and second portions 452 and 454 and first and second meandered connecting lines 456 and 457 electrically connecting the respective first and second portions 452 and 454 of the second element 414 to the sensor portion 420. In the illustrated embodiment, the first element 412 does not include a meandered portion and the second element 414 includes two meandered portions (first and second meandered connecting lines 456 and 457). The antenna tag 400 may be made from a metal layer 483 on a substrate 485 as described further elsewhere herein.

The antenna portion 410 may alternatively be described as including a first dipole portion 461 disposed closer to the sensor portion 420 and a second dipole portion 463 disposed farther from the sensor portion 420. The first dipole portion 461 is electrically connected to the sensor portion 420 through linear connecting lines 458 and 459 and the second dipole portion 463 is electrically connected to the sensor portion 420 through meandered connecting lines 456 and 457.

In some embodiments, a first conductor length separates the first dipole portion 461 from the terminals 430 (see FIG. 6) of the sensor portion 420 and a second conductor length separates the second dipole portion 463 from the terminals 430. The conductor length separating a dipole portion from the terminals 430 can be understood to be the shortest conductive path length between the dipole portion and the terminals. In the illustrated embodiment, the second conductor length is larger than the first conductor length since the first and second meandered connecting lines 456 and 457 are substantially longer than the first and second linear connecting lines 458 and 459. As is known in the art, phase differences between different antenna elements can be adjusted to adjust the main beam direction of the antenna. The phase difference between the first dipole portion 461 and the second dipole portion 463 can be adjusted by changing the difference between the second and first conductor lengths. In some embodiments, the difference between the second and first conductor lengths is selected such that the antenna tag has a largest directivity in a predetermined direction. This difference in lengths can be adjusted by altering the geometry of the first and second meandered connecting lines 456 and 457. For example, the lengths of the first and second meandered connecting lines 456 and 457 can be shortened by reducing the distance the first and second meandered connecting lines 456 and 457 extend in the length direction (z′-direction referring to the x′-y′-z′ coordinate system depicted in FIGS. 4-6) or the lengths of the first and second meandered connecting lines 456 and 457 can be lengthened by including more meanders.

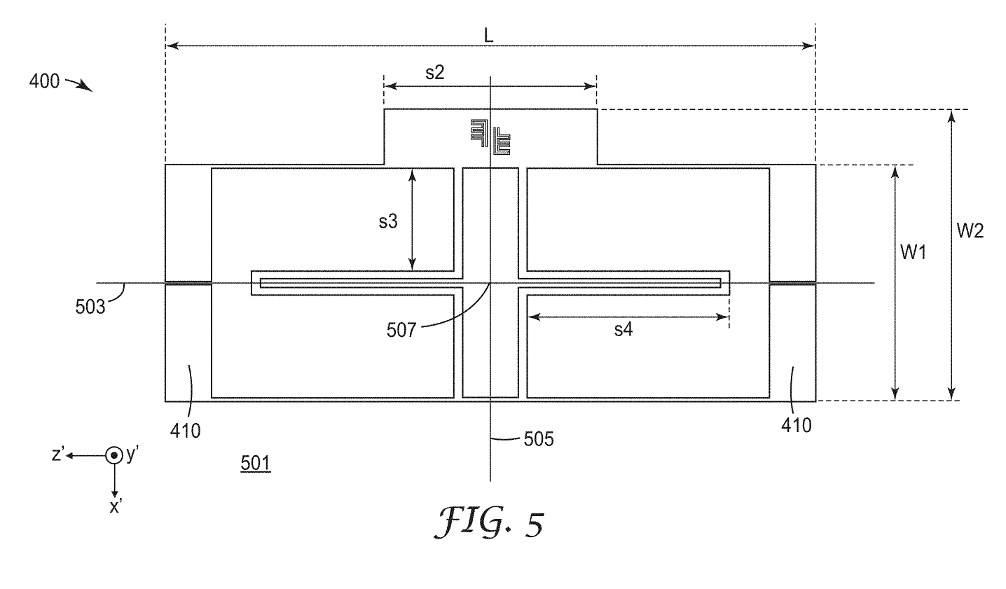

In some embodiments, the antenna tag 400 has similar symmetry and geometric properties as described for antenna tag 100. FIG. 5 is a top view of the antenna tag 500 disposed in a first plane 501 (the y′-z′ plane). Second plane 503 is orthogonal to the first plane 501 and third plane 505 is orthogonal to the first and second planes 501 and 503. An axis 507 (parallel to the y′-axis) which is perpendicular to the first plane 501 is indicated. In the illustrated embodiment, axis 507 is the intersection of the second and third planes 503 and 505. The antenna portion 510 is symmetric under reflection about the second plane 503 and symmetric under reflection about third plane 505. The antenna portion 410 has a length L and a width W1 and the antenna tag 400 has a length L and a width W2. In some embodiments, L>W2>W1. In some embodiments, the length L is in a range of 0.7 to 1.1, or 0.73 to 0.95, or 0.77 to 0.95 times the predetermined wavelength. In some embodiments, the width W1 is in a range of 0.3 to 0.45 times the length L, and the width W2 is in a range of 0.35 to 0.55 times the length L. In some embodiments, L is in a range of 220 mm to 350 mm, or 250 mm to 310 mm. Dimensions g (gap separating the first and second dipole portions 461 and 463) and s1 are depicted in FIG. 4, dimensions s2, s3, and s4 are depicted in FIG. 5, and dimensions s5 and s6 are depicted in FIG. 6. In some embodiments, s1 is in a range of 0.03 to 0.05 times the length L, s2 is in a range of 0.25 to 0.4 times the length L, s3 is in a range of 0.12 to 0.2 times the length L, s4 is in a range of 0.25 to 0.4 times the length L, s5 is in a range of 0.025 to 0.04 times the length L, and s6 is in a range of 0.03 to 0.05 times the length L. In some embodiments, g is in a range of 0.5 to 2 mm.

FIG. 6 is a top view of a portion of the sensor portion 420 of the antenna tag 400. The sensor portion 420 includes terminals 430 (e.g., corresponding to terminals 131 and 133) for attaching a chip 435. The sensor portion 420 includes a patterned conductor 422 which defines a gap pattern 424 in the patterned conductor 422. In some embodiments, when the antenna tag 400 is disposed in the first plane 501, the gap pattern is symmetric under rotations of 180 degrees about the axis 507, which passes through a midpoint of the terminals 430.

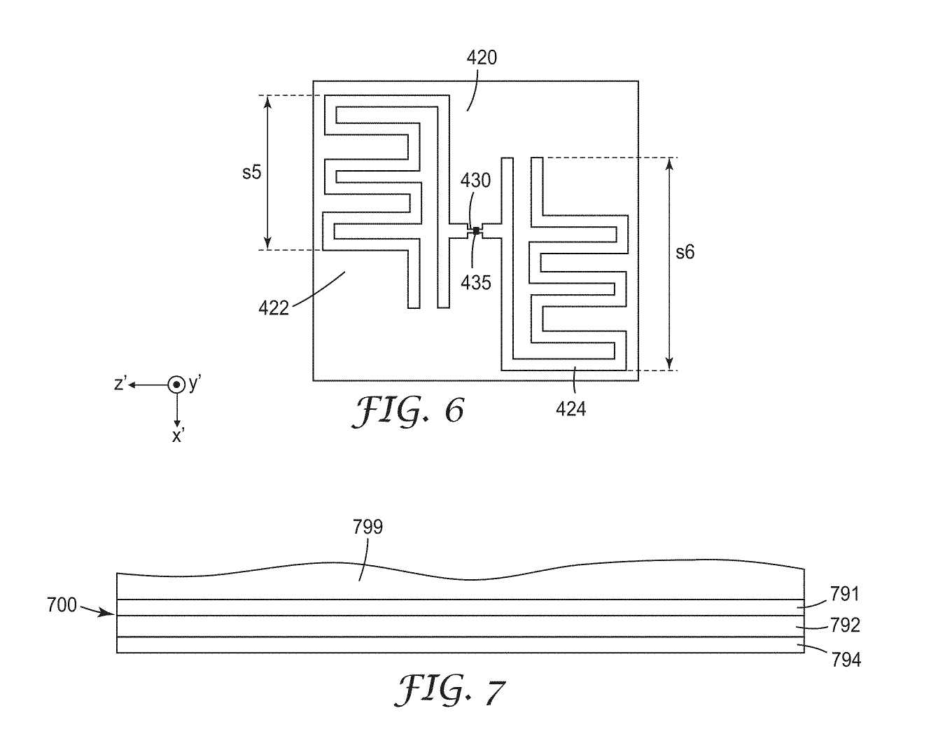

FIG. 7 is a schematic side view of antenna tag 700 showing a presence of a material 799 on a top of the antenna tag 700. The antenna tag 700 may correspond to antenna tag 100 or antenna tag 400, for example. The antenna tag 700 includes conductor layer 791 on substrate 792. Conductor layer 791 is a layer of conductor which is patterned to define the antenna portion and sensor portion of the antenna tag and substrate 792 is a layer on which the conductor layer 791 is disposed. For example, an antenna tag can be made by patterning (e.g., etching) a metal layer (e.g., copper) disposed on a flexible polymeric (e.g., polyimide) substrate. In some embodiments, an adhesive layer 794 is also included adjacent substrate 792 opposite the conductor layer 791 for attaching the antenna tag 700 to a surface (e.g., a curved surface of a rotor blade or wing). In some embodiments, the material 799 is a dielectric or magnetic material. A dielectric material is a material having a significant dielectric response (e.g., relative permittivity greater than that of air, or greater than 1.1, or preferably greater than 2, or more preferably greater than 3) at a frequency in the predetermined UHF frequency range. Relative permittivity and relative permeability refers to the real parts of the complex relative permittivity and complex relative permeability, respectfully, except where indicated otherwise or the where context clearly indicates differently. For example, the dielectric material may be ice or water which has a relative permittivity of about 80. A magnetic material is a material having a significant magnetic response (e.g., relative permeability greater than that of air, or greater than 1.1, or preferably greater than 2, or more preferably greater than 3) at a frequency in the predetermined UHF frequency range. For example, the magnetic material may be ferromagnetic materials or materials comprising ferromagnetic particles.

In some embodiments, the material 799 is water or ice, and the antenna tag 700 provides an indication of a build-up of water or ice. In some embodiments, the material 799 is a coating applied onto the conductive layer, and the antenna tag 700 provides an indication of an erosion of the coating. In some embodiments, a coating is included and the antenna tag is responsive to both the buildup of ice or water and the erosion of the coating. In some embodiments, the antenna tag 700 is more sensitive to the presence of dielectric or magnetic material near or on a sensor portion of the antenna tag 700 and less sensitive to the presence of dielectric or magnetic material near or no other portions of the antenna tag 700. In some embodiments, the sensor portion (e.g., sensor portion 120 or 420) includes a patterned conductor (e.g., patterned conductor 122 or 422) which provides a capacitance at the terminals that depends on an amount of dielectric material (e.g., water or ice present) on the sensor portion.

In some embodiments, an antenna tag is configured such that the sensor portion of an antenna tag can be disposed in a region where it is desired to detect ice buildup or erosion, for example. In some embodiments, the antenna tag is disposed on and conforms to a curved surface. For example, either of the antenna tag 100 and the antenna tag 400 can be disposed on a curved surface of a rotor blade such that the antenna tag conforms to the curved surface. In some embodiments, it is desired that the sensor portion be disposed on a leading edge of the rotor blade when the antenna tag is disposed on and conforms to the curved surface of the rotor blade. In such embodiments, an antenna tag, such as the antenna tag 400, where the sensor portion is disposed proximate a side of the antenna tag is typically preferred. In some embodiments, a wind turbine includes one or more rotor blades each having a leading edge, where at for at least one rotor blade, at least one antenna tag of the present description is disposed on and conforms to the rotor blade with the sensor portion of the antenna tag disposed on the leading edge. In some embodiments, a plurality of the antenna tags is disposed on and conforms to the curved major surface of each rotor blade.

It will be understood that the curve of the curved surface refers to the general shape of the surface (e.g., rotor blade surface) and does not refer to small variations or fluctuations resulting from surface roughness.

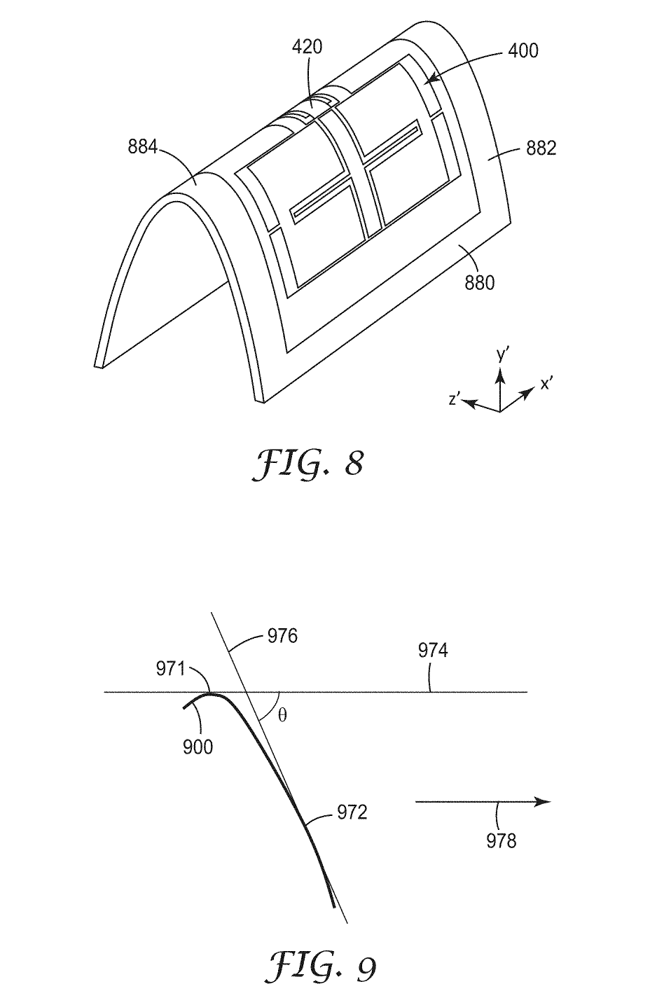

FIG. 8 is a perspective cross-sectional view of a portion of a rotor blade 880 having a curved surface 882 and having a leading edge 884. Curved surface 882 is an outermost major surface of the rotor blade 880. The antenna tag 400 is disposed on and conforms to the curved surface 882 and the sensor portion 420 is disposed on the leading edge 884 of the rotor blade 880.

FIG. 9 is a schematic cross-sectional view of an antenna tag 900 in a cross-section perpendicular to a length of the antenna tag 900. The antenna tag 900 is curved so that it conforms to a curved surface (e.g., curved surface 882). A plane 974 tangent to the antenna tag 900 at location 971 is illustrated, and a plane 976 tangent to the antenna tag 900 at location 972 is illustrated. Location 971 may be a location in the sensor portion (e.g., at a center of the sensor portion) and location 972 may be a location in the antenna portion (e.g., at a center of the antenna portion). The planes 974 and 976 define an angle θ therebetween. In some embodiments, θ is at least 30 degrees, or at least 45 degrees, or at least 50 degrees. In some embodiments, θ is no more than 90 degrees, or no more than 85 degrees, or no more than 80 degrees. For example, in some embodiments, θ is in a range of 30 degrees to 90 degrees, or 45 degrees to 90 degrees, or 50 degrees to 85 degrees. In some embodiments, the antenna tag has a directivity of at least 3 dBi, or at least 4 dBi, or at least 4.5 dBi, or at least 5 dBi in the predetermined direction 978 which is parallel or substantially parallel to the plane 974 and which makes an oblique angle (θ) to the plane 976. In some embodiments, the predetermined direction 978 is substantially along a direction from the antenna tag 900 to a reader antenna when the antenna tag 900 is closest to the reader antenna.

A predetermined direction is substantially along a direction if it is within 30 degrees of that direction. In some embodiments, a predetermined direction described as substantially along a direction is within 20 degrees, or within 10 degrees, or within 5 degrees of that direction. A predetermined direction is substantially parallel to a plane if it makes an angle with the plane of no more than 30 degrees. In some embodiments, a predetermined direction described as substantially parallel to a plane may make an angle with the plane of no more than 20 degrees, or 10 degrees, or 5 degrees.

In some embodiments, the antenna tag (e.g., antenna tag 100 or antenna tag 400) has a read range in a desired range when a reader supplies a specified radiated power. It is typically preferred that the read range is at least 6 m for an effective isotropic radiated power (EIRP) of no more than a limit specified by the relevant regulatory authority. For example, the Federal Communications Commission (FCC) limits the EIRP in the band from 902 to 928 MHz to 36 dBm. In some embodiments, for an EIRP of 36 dBm, the antenna tag has a maximum read range of at least 6 m, or at least 7 m, or at least 7.5 m, or at least 8 m, or at least 8.5 m, or at least 9 m. In some embodiments, for an EIRP of 36 dBm at the predetermined UHF frequency, the antenna tag has a maximum read range of up to 12 m, or up to 11 m, or up to 10 m. The specified read ranges are for an EIRP of 36 dBm at the predetermined UHF frequency and for the antenna tag in air unless specified differently. The maximum read range may also be in any of these ranges when the antenna tag is disposed on an epoxy/fiberglass composite such as that if a rotor blade.

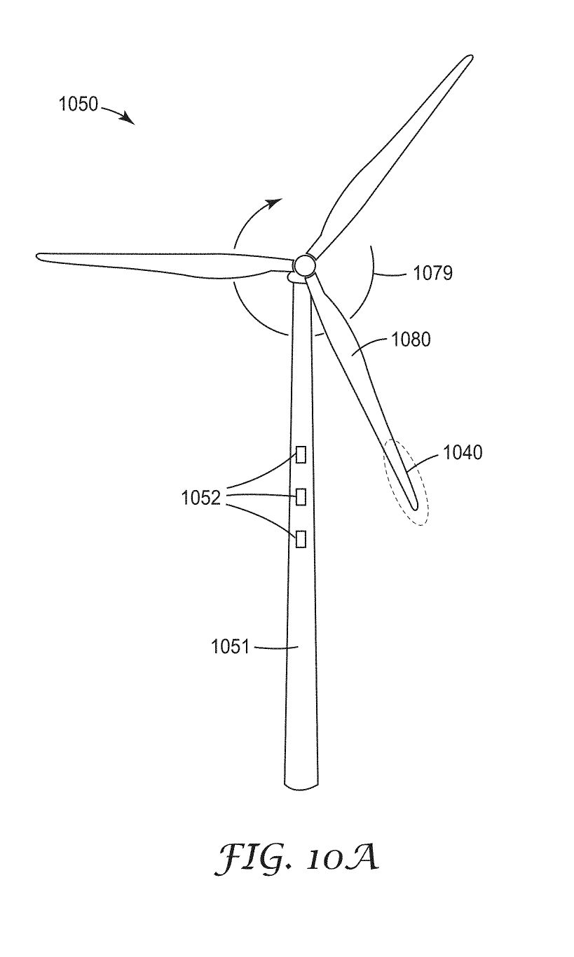

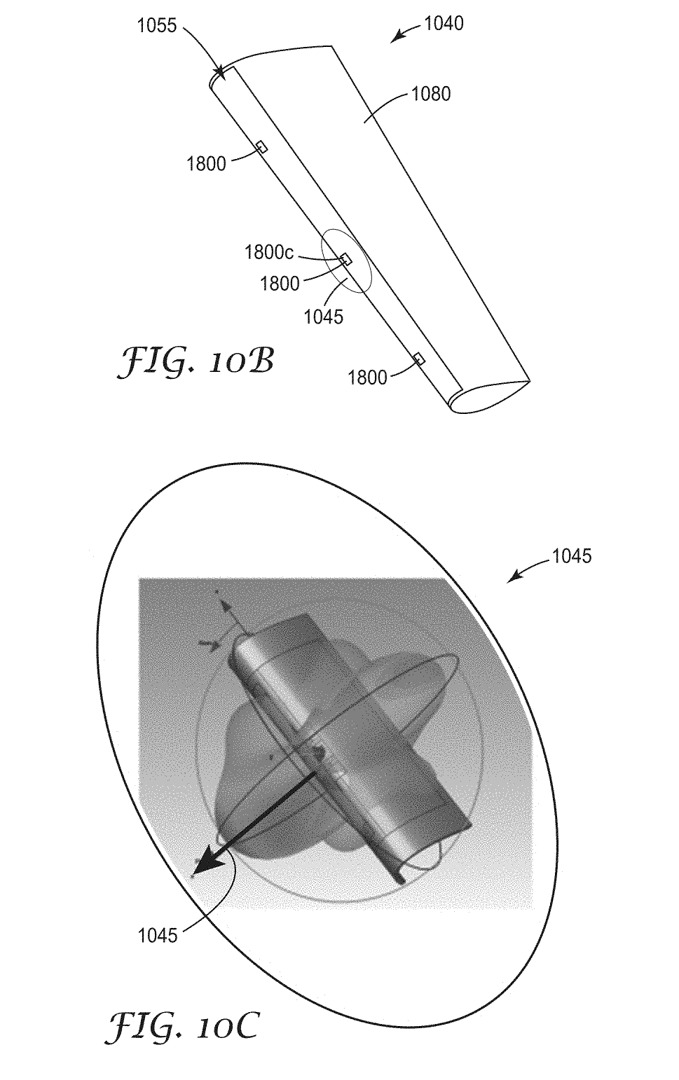

FIG. 10A is a schematic illustration of a wind turbine 1050 including three rotor blades 1080. In other embodiments, more than three rotor blades or less than three rotor blades may be utilized. In some embodiments, the wind turbine includes one or more reader antennas disposed proximate the at least one antenna tag. A plurality of reader antennas 1052 are disposed on a tower 1051 of the wind turbine in the illustrated embodiment. In some embodiments, a plurality of antenna tags is disposed on and conforms to the curved major surface of each rotor blade 1080. In some embodiments, the wind turbine includes a plurality of reader antennas 1052 disposed proximate the antenna tags. In some embodiments, for each rotor blade 1080, a plurality of antenna tags is disposed on and conforms to a curved major surface of the rotor blade 1080 and is in one-to-one correspondence with the plurality of reader antennas 1052. For example, the region 1040, which is illustrated in FIG. 10B, includes three antenna tags 1800 disposed in a leading-edge protection tape 1055. The three antenna tags 1800 are in one-to-one correspondence with the three reader antennas 1052 in the illustrated embodiment. In some embodiments, each of the rotor blades 1080 includes a plurality of antenna tags 1800 disposed on and conforming to the curved major surface of the rotor blade. In some embodiments, for each rotor blade 1080, the plurality of antenna tags 1800 disposed on and conforming to the curved major surface of the rotor blade is in one-to-one correspondence with the plurality of reader antennas 1052.

FIG. 10C is an illustration of the region 1045 of FIG. 10B showing a distribution of directivity of one of the center antenna tag 1800c of the plurality of antenna tags 1800. The directivity is largest along the predetermined direction 1078. The direction of rotation 1079 of the rotor blades is illustrated in FIG. 10A. When the rotor blade including the antenna tag 1800 depicted in FIG. 10C is approximately vertical or parallel with the tower 1051 and pointing downward, the antenna tag 1800c is closest to the reader antennas 1052. At this time, the predetermined direction 1078 is substantially along a direction (substantially into the page of FIG. 10A) from the antenna tag 1800c to the corresponding reader antenna 1052. Since the center antenna tag 1800c is depicted in FIG. 10C, the corresponding reader antenna 1052 is the center reader antenna in this case.

In some embodiments, the antenna tag includes a means to adjust a phase difference between the first and second dipole portions (e.g., first and second dipole portions 461 and 463). The phase difference between the first and second dipole portions can be adjusted to provide a desired main beam direction. For a given length of the linear connecting lines 458 and 459, this phase difference can be set by choosing the lengths of the meandered connecting lines 456 and 457. For a given rotor blade geometry, the lengths of the meandered connecting lines 456 and 457 needed to give the desired beam direction can be determined. However, in some embodiments, it is desired that an antenna tag be used for a variety of rotor blades and it is desired that the phase difference be adjustable to different values for different rotor blades so that the directivity can be tailored to each rotor blade.

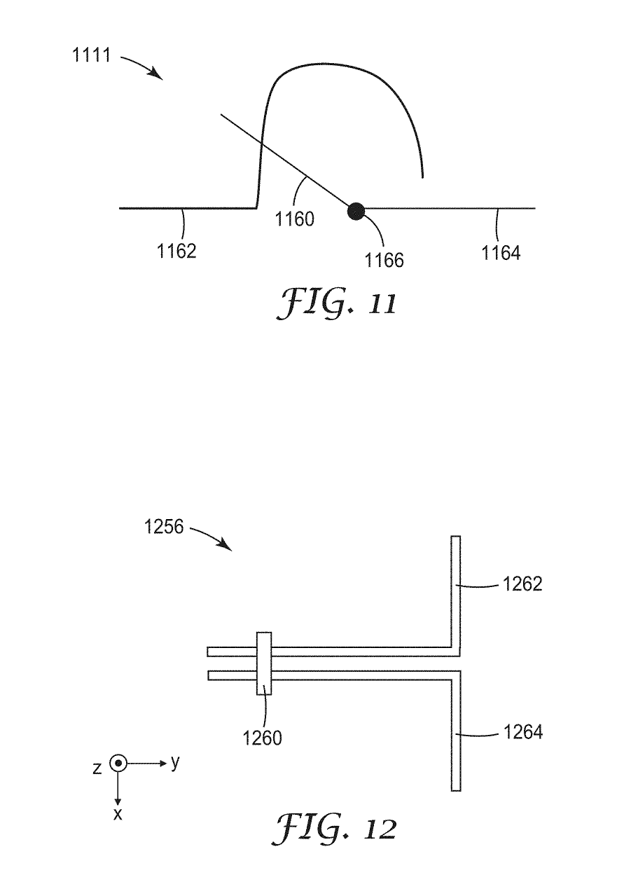

Circuits having an adjustable phase difference are known in the art and can be used to adjust the phase difference. Active phase shift circuits can be used, but it is typically preferred that the antenna tag be passive so passive circuits which provide an adjustable phase are typically preferred. Such circuits can be incorporated in the linear connecting lines 458 and 459 and/or in the meandered connecting lines 456 and 457. For example, FIG. 11 is a schematic illustration of a circuit 1111 that can be used in place of a segment or a portion of the linear connecting lines 458 and 459 and/or a segment or portion of the meandered connecting lines 456 and 457 to adjust conductor lengths and thereby phase differences between first and second dipole portions 461 and 463. Circuit 1111 includes a first conductor 1162 having a curved portion, a second conductor 1164 and a third conductor 1160 configured to rotate about pivot 1166. Circuit 1111 has a conductor length that depends the angular position of the third conductor about pivot 1166. Rotating the third conductor in the clockwise direction increases the conductor length and rotating the third conductor in the counterclockwise direction decreases the conductor length.

In some embodiments, the phase difference is adjusted by replacing the meandered connecting lines 456 and 456 with lines having an adjustable conductor length. FIG. 12 is a schematic top view of connector 1256 which has a first portion 1262 and a second portion 1264 electrically connected by movable connecting element 1260. The connector 1256 can be used in place of meandered connecting line 456, and a connector having a movable connecting element can similarly be used in place of meandered connecting line 457. Moving movable connecting element 1260 in the plus y-direction decreases the conductor length of connector 1256 and moving movable connecting element 1260 to the negative y-direction increases the conductor length of connector 1256. Thus, a suitable position of the movable connecting element 1260 can be selected to adjust a phase difference between the first and second dipole portions.

In some embodiments, the antenna tag includes a chip attached to the terminal of the sensor portion. In some embodiments, the chip includes an integrated circuit. In some embodiments, the chip includes a reactance autotuning integrated circuit which may be referred to as adaptive circuitry. Preferably, the reactance autotuning integrated circuit includes a radio frequency identification (RFID) unit. Typically, such a RFID unit includes radio frequency (RF) circuits, logic, and memory. In some embodiments, the reactance autotuning integrated circuit, in particular the RFID unit, functions in response to an RF signal, in particular to a uniquely coded RF signal. For instance, if the antenna tag including the chip is placed into an RF field including the RF signal, the RFID unit becomes stimulated and transmits a uniquely coded signal. In some embodiments, the chip is configured to report changes in impedance using a multi-bit sensor code.

Preferably, the reactance autotuning integrated circuit including the RFID sensing unit includes an inductor, preferably to match or substantially match the chip impedance to the input impedance at the terminals of the antenna tag. In some embodiments, it is preferred that the inductance value of the inductor may be tuned by the magnetic properties of certain materials such as ferromagnetic materials or materials comprising ferromagnetic particles. For example, silicon carbide particles or ferromagnetic particles commercially available under Bayferrox powder (Bayer AG, Leverkusen, Germany) or Sendust. A loss of the material including said ferromagnetic particles gives rise to a decrease or increase of the turn-on-threshold (ToT) of the system. This would correspond to an existing or non-existing of the responsive material, which also corresponds to an information that erosion on this area has taken place.

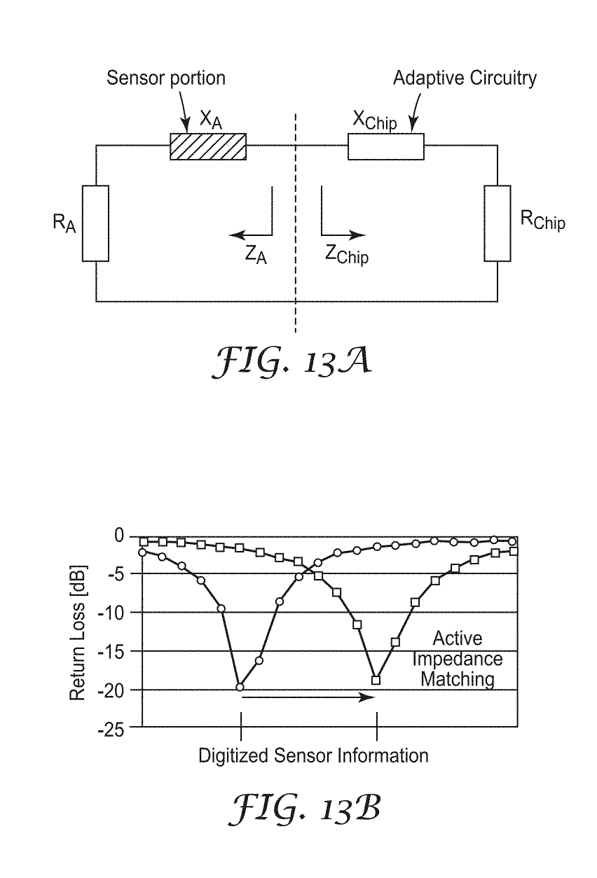

It is further preferred that the reactance autotuning integrated circuit including the RFID sensing circuit includes a variable input capacitor, which allows for optimizing the impedance matching of the chip impedance to the input impedance at the terminals of the antenna tag. In FIG. 13A, an impedance matching model is illustrated and in FIG. 13B a shift of digitized sensor information (e.g., a digital sensor code) due to a shift in impedance provided by the reactance autotuning integrated circuit is illustrated. Preferably, the autotuning function of the chip minimizes the return loss and saves the encoded/digital value of the capacitance into the memory of the chip. This has the effect that indirect measurements of the antenna tag impedance may be carried out. This measurement principle has the further advantage that measurement of material presence having significant dielectric or magnetic response at the system frequency becomes possible. Accordingly, this allows the detection of wear or erosion of material and the detection of ice buildup.

It is preferred that the sensor portion includes a sensor having a capacitor element having a capacitance which changes if the field lines through the capacitor element cross high permittivity materials. For example, in some embodiments, the sensor portion includes a patterned conductor providing a capacitance at the terminals, where the capacitance depends on an amount of a dielectric or magnetic material present on the sensor portion, for example. In some embodiments, the patterned conductor defines capacitive fingers which provides the capacitance at the terminals. High permittivity materials are these commonly known in the art, such as water having a relative permittivity of about 80. When the field lines between the electrodes of the capacitor element cross high permittivity materials such as water, the capacitance of the sensor portion increases. This increase of the capacitance will be compensated by a decrease of capacitance of the autotuning integrated circuit. Accordingly, this is equivalent to a digitized capacitance value, and in the present example, will also result in a lower sensor code. Accordingly, it is possible to detect the presence of water with the reactance autotuning integrated circuit. Moreover, the dielectric properties of water change substantially at UHF frequencies (e.g., frequencies in the range of from 865 to 928 MHz) if the water freezes, which may result in a higher sensor code allowing the detection of ice.

In some embodiments, the antenna tag is also configured to detect temperature. For example, the antenna tag may contain a chip containing a temperature sensor (e.g., utilizing a temperature sensitive diode). In combination with the detection of the presence of water, the measured temperature allows for the determination of the formation of ice on the surface. In some embodiments, a system including a reader and an antenna tag determines a temperature and a change in impedance over time which allows a buildup of ice to be detected.

Useful chips (e.g., with a reactance autotuning integrated circuit) that can be incorporated into the antenna tags of the present description are known in the art. For example, such chips are described in U.S. Pat. Appl. Publ. No. 2016/0267769 (Rokhsaz et al.). Useful chips include the Magnus® S chips available from RFMicron (Austin, Tex.).

Techniques to manufacture radio frequency identification (RFID) tags known in the art can be used to make the antenna tags of the present description. For example, the antenna tags can be made by patterning (e.g., by chemical etching) a metal layer (e.g., copper or silver) disposed on a flexible polymeric substrate (e.g., polyimide, polyethylene terephthalate, or polyetherimide). The metal layer may have a thickness in the range of 10 micrometers to 100 micrometers, or 10 micrometers to 50 micrometers, or 10 to 25 micrometers, for example. The substrate is preferably sufficiently flexible that the antenna tag can be disposed on and conform to the surface on which it is desired to attach the antenna tag. For example, polyimide having a thickness of no more than 50 micrometers (e.g., about 25 micrometers) is sufficiently flexible for many surfaces of interest (e.g., surface of a rotor blade). Alternatively, antenna tags can be made by printing a conductive material (e.g., inkjet printable conductive inks (e.g., containing silver nanoparticles) or screen-printable silver paste) onto a flexible polymeric substrate.

In some embodiments, an ultra-high frequency (UHF) antenna tag includes a sensor portion and an antenna portion. The sensor portion includes terminals for attaching a chip having a chip impedance. The sensor portion is responsive to a presence of a dielectric or magnetic material proximate the sensor portion (e.g., disposed directly or indirectly on the sensor portion). The antenna portion includes first and second elements electrically connected to the sensor portion, where at least one of the first and second elements includes at least one meandered portion. The antenna tag is configured (e.g., by an appropriate choice of the geometry of the antenna portion) such that at a predetermined UHF frequency the antenna tag has an input impedance at the terminals substantially matched to the chip impedance, the antenna tag has a directivity of at least 4 dBi, or at least 4.5 dBi, or at least 5 dBi, in a predetermined direction, and the antenna tag has a radiation efficiency of at least 60 percent.

In some embodiments, an ultra-high frequency (UHF) antenna tag including a sensor portion and an antenna portion is provided. The sensor portion includes terminals for attaching a chip having a chip impedance. The sensor portion is responsive to a presence of a dielectric or magnetic material proximate the sensor portion (e.g., disposed directly or indirectly on the sensor portion). The antenna portion includes first and second meandered loop elements disposed on opposite sides of the sensor portion and electrically connected to the sensor portion such that the first meandered loop element and the sensor portion defines a first electrically closed loop and the second meandered loop element and the sensor portion defines a second electrically closed loop. The antenna tag is configured (e.g., by an appropriate choice of the geometry of the antenna portion) such that at a predetermined UHF frequency: the antenna tag has an input impedance at the terminals substantially matched to the chip impedance; the antenna tag has a radiation efficiency of at least 60 percent; and for an effective isotropic radiated power (EIRP) of 36 dBm, the UHF antenna tag has a maximum read range of at least 6 m, or at least 7 m, or at least 7.5 m, or at least 8 m, or at least 8.5 m.

In some embodiments, an ultra-high frequency (UHF) antenna tag is configured to be disposed on and conform to a curved surface (e.g., a curved surface of a rotor blade). The UHF antenna tag includes a sensor portion and an antenna portion. The sensor portion includes terminals for attaching a chip having an impedance. The sensor portion responsive to a presence a dielectric or magnetic material proximate the sensor portion (e.g., disposed directly or indirectly on the sensor portion). The antenna portion includes a first dipole portion disposed closer to the sensor portion and a second dipole portion disposed farther from the sensor portion, where the first and second dipole portions are electrically connected to the sensor portion. The antenna tag is configured (e.g., by an appropriate choice of the geometry of the antenna portion) such that at a predetermined UHF frequency when the antenna tag is disposed on and conforms to the curved surface: the antenna tag has an input impedance at the terminals substantially matched to the impedance of the chip; the antenna tag has a directivity of at least 3 dBi, or at least 4 dBi, or at least 4.5 dBi, or at least 5 dBi, in a predetermined direction; and the antenna tag has a radiation efficiency of at least 45 percent, or at least 50 percent, or at least 55 percent, or at least 60%.

In some embodiments, a wind turbine includes one or more rotor blades where each rotor blade includes a leading edge and where for at least one rotor blade, at least one ultra-high frequency (UHF) antenna tag is disposed on and conforms to a curved major surface of the rotor blade. Each antenna tag includes a sensor portion and an antenna portion. The sensor portion is disposed on the leading edge of the rotor blade and is responsive to a presence a dielectric or magnetic material proximate the sensor portion (e.g., disposed directly or indirectly on the sensor portion). The sensor portion includes terminals and a chip is electrically connected to the terminals. The antenna portion includes a first dipole portion disposed closer to the sensor portion and a second dipole portion disposed farther from the sensor portion. The first and second dipole portions are electrically connected to the sensor portion. A first conductor length separates the first dipole portion from the sensor portion, and a second conductor length separates the second dipole portion from the sensor portion. The wind turbine further includes one or more reader antennas disposed proximate the at least one antenna tag. For each antenna tag and a reader antenna in the one or more reader antennas disposed to communicate with the antenna tag, a difference between the second and first conductor lengths is selected such that when the antenna tag is closest to the reader antenna, the antenna tag has a directivity of at least 3 dBi, or at least 4 dBi, or at least 4.5 dBi, or at least 5 dBi, in a direction toward the reader antenna. The antenna tag may have a radiation efficiency of at least 45 percent, or at least 50 percent, or at least 55 percent, or at least 60 percent. On or more readers may include the one or more reader antennas. The directivity and efficiency may be specified at an operating frequency of the antenna tag/reader which may be in a range of 865 to 928 MHz.

The following is a list of exemplary embodiments of the present description.

Embodiment 1 is an ultra-high frequency (UHF) antenna tag comprising: a sensor portion comprising terminals for attaching a chip having a chip impedance, the sensor portion responsive to a presence of a dielectric or magnetic material proximate the sensor portion; an antenna portion comprising first and second elements electrically connected to the sensor portion, at least one of the first and second elements comprising at least one meandered portion, the antenna tag configured such that at a predetermined UHF frequency:

the antenna tag has an input impedance at the terminals substantially matched to the chip impedance;

the antenna tag has a directivity of at least 4 dBi in a predetermined direction; and
the antenna tag has a radiation efficiency of at least 60 percent.

Embodiment 2 is the UHF antenna tag of Embodiment 1, wherein when the antenna tag is disposed in a first plane, the antenna portion is symmetric under reflection about a second plane orthogonal to the first plane and symmetric under reflection about a third plane orthogonal to the first and second planes.

Embodiment 3 is the UHF antenna tag of Embodiment 1 or 2, wherein the sensor portion comprises a patterned conductor providing a capacitance at the terminals, the capacitance depending on an amount of water or ice present on the sensor portion.

Embodiment 4 is the UHF antenna tag of Embodiment 3, wherein the patterned conductor defines a gap pattern in the patterned conductor such that when the antenna tag is disposed in a first plane, the gap pattern is symmetric under rotations of 180 degrees about an axis perpendicular to the first plane.

Embodiment 5 is the UHF antenna tag of Embodiment 1, wherein the first element is disposed closer to the sensor portion and the second element is disposed farther from the sensor portion.

Embodiment 6 is the UHF antenna tag of Embodiment 5, wherein the first element comprises first and second portions and first and second linear connecting lines electrically connecting the respective first and second portions of the first element to the sensor portion.

Embodiment 7 is the UHF antenna tag of Embodiment 5 or 6, wherein the second element comprises first and second portions and first and second meandered connecting lines electrically connecting the respective first and second portions of the second element to the sensor portion.

Embodiment 8 is the UHF antenna tag of Embodiment 1 having a width and a length greater than the width, wherein the length is in a range of 0.55 to 0.73 times a predetermined wavelength, the predetermined wavelength being the speed of light in vacuum divided by the predetermined UHF frequency.

Embodiment 9 is the UHF antenna tag of Embodiment 1 having a width and a length greater than the width, wherein the length is in a range of 0.73 to 0.95 times a predetermined wavelength, the predetermined wavelength being the speed of light in vacuum divided by the predetermined UHF frequency.

Embodiment 10 is the UHF antenna tag of Embodiment 1, wherein for an effective isotropic radiated power (EIRP) of 36 dBm at the predetermined UHF frequency, the UHF antenna tag has a maximum read range of at least 6 m, or at least 7 m, or at least 7.5 m, or at least 8 m.

Embodiment 11 is a wind turbine comprising a rotor blade and the UHF antenna tag of any one of Embodiments 1 to 10 disposed on and conforming to a major surface of the rotor blade.

Embodiment 12 is an ultra-high frequency (UHF) antenna tag comprising: a sensor portion comprising terminals for attaching a chip having a chip impedance, the sensor portion responsive to a presence of a dielectric or magnetic material proximate the sensor portion; an antenna portion comprising first and second meandered loop elements disposed on opposite sides of the sensor portion and electrically connected to the sensor portion such that the first meandered loop element and the sensor portion defines a first electrically closed loop and the second meandered loop element and the sensor portion defines a second electrically closed loop, the antenna tag configured such that at a predetermined UHF frequency:

the antenna tag has an input impedance at the terminals substantially matched to the chip impedance;

the antenna tag has a radiation efficiency of at least 60 percent; and

for an effective isotropic radiated power (EIRP) of 36 dBm, the UHF antenna tag has a maximum read range of at least 6 m.

Embodiment 13 is the UHF antenna tag of Embodiment 12 having a width and a length greater than the width, wherein the length is in a range of 0.55 to 0.69 times a predetermined wavelength, the predetermined wavelength being the speed of light in vacuum divided by the predetermined UHF frequency.

Embodiment 14 is the UHF antenna tag of Embodiment 12 having a directivity of at least 4 dBi, or at least 5 dBi in a direction normal to a plane of the antenna tag.

Embodiment 15 is a wind turbine comprising a rotor blade and the UHF antenna tag of any one of Embodiments 12 to 14 disposed on and conforming to a major surface of the rotor blade.

Embodiment 16 is an ultra-high frequency (UHF) antenna tag configured to be disposed on and conform to a curved surface, the UHF antenna tag comprising:
a sensor portion comprising terminals for attaching a chip having an impedance, the sensor portion responsive to a presence a dielectric or magnetic material proximate the sensor portion;
an antenna portion comprising a first dipole portion disposed closer to the sensor portion and a second dipole portion disposed farther from the sensor portion, the first and second dipole portions electrically connected to the sensor portion, the antenna tag configured such that at a predetermined UHF frequency when the antenna tag is disposed on and conforms to the curved surface:

the antenna tag has an input impedance at the terminals substantially matched to the impedance of the chip;

the antenna tag has a directivity of at least 3 dBi in a predetermined direction; and

the antenna tag has a radiation efficiency of at least 45 percent.

Embodiment 17 is the UHF antenna tag of Embodiment 16, wherein a first conductor length separates the first dipole portion from the terminals and a second conductor length separates the second dipole portion from the terminals, a difference between the second and first conductor lengths being selected such that the antenna tag has a largest directivity in the predetermined direction.

Embodiment 18 is the UHF antenna tag of Embodiment 16, wherein a fixed first conductor length separates the first dipole portion from the terminals and an adjustable second conductor length separates the second dipole portion from the terminals.

Embodiment 19 is the UHF antenna tag of Embodiment 16 further comprising a means to adjust a phase difference between the first and second dipole portions.

Embodiment 20 is a wind turbine comprising the UHF antenna tag of any one of Embodiments 16 to 19 disposed on and conforming to a curved major surface of a rotor blade.

Embodiment 21 is the wind turbine of Embodiment 20, wherein the sensor portion is disposed on a leading edge of the rotor blade.

Embodiment 22 is the wind turbine of Embodiment 20 further comprising a reader antenna disposed to communicate with the UHF antenna tag, wherein when the UHF antenna tag is closest to the reader antenna, the predetermined direction is substantially along a direction from the UHF antenna tag to the reader antenna.

Embodiment 23 is a wind turbine comprising one or more rotor blades, each rotor blade comprising a leading edge, wherein for at least one rotor blade, at least one ultra-high frequency (UHF) antenna tag is disposed on and conforms to a curved major surface of the rotor blade, each antenna tag comprising:
a sensor portion comprising terminals, the sensor portion disposed on the leading edge of the rotor blade, the sensor portion responsive to a presence a dielectric or magnetic material proximate the sensor portion;
a chip electrically connected to the terminals;
an antenna portion comprising a first dipole portion disposed closer to the sensor portion and a second dipole portion disposed farther from the sensor portion, the first and second dipole portions electrically connected to the sensor portion, a first conductor length separating the first dipole portion from the sensor portion, a second conductor length separating the second dipole portion from the sensor portion, the wind turbine further comprising one or more reader antennas disposed proximate the at least one antenna tag, wherein for each antenna tag and a reader antenna in the one or more reader antennas disposed to communicate with the antenna tag, a difference between the second and first conductor lengths is selected such that when the antenna tag is closest to the reader antenna, the antenna tag has a directivity of at least 3 dBi in a direction toward the reader antenna.

Embodiment 24 is the wind turbine of Embodiment 23, wherein a plurality of the antenna tags is disposed on and conforms to the curved major surface of each rotor blade.

Embodiment 25 is the wind turbine of Embodiment 24, wherein the one or more reader antennas comprises a plurality of reader antennas.

Embodiment 26 is the wind turbine of Embodiment 25, wherein for each rotor blade, the plurality of antenna tags disposed on and conforming to the curved major surface of the rotor blade is in one-to-one correspondence with the plurality of reader antennas.

### EXAMPLES

### Example 1

An antenna tag as shown in FIGS. 1-3 was modeled and fabricated. The dimensions shown in FIGS. 1-2 were L=200 mm, W=74 mm, d1=19 mm, d2=68 mm, d3=38 mm, d4=20.7 mm, d5=8.5 mm, d6=18.5 mm, d7=81 mm, d8=15 mm.

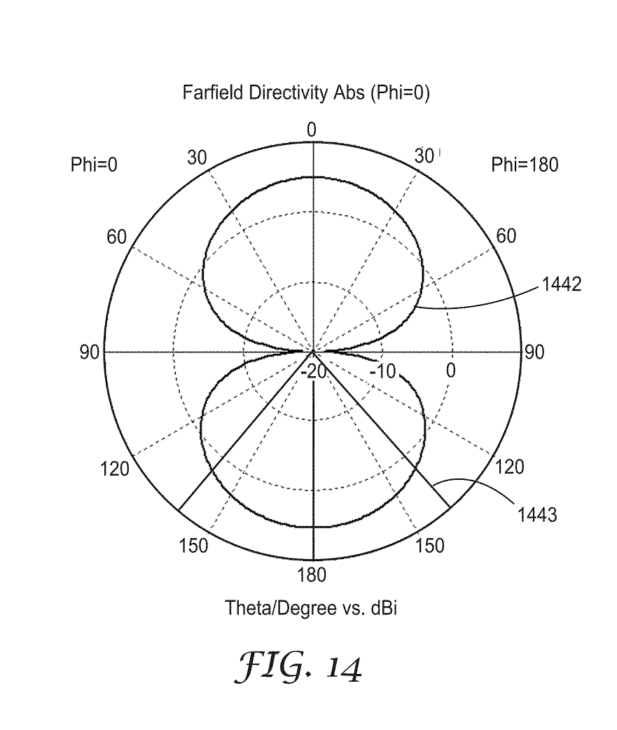

FIGS. 14-19 show results for when the antenna tag is disposed in a plane as in FIG. 1, for example. FIG. 14 is a plot of the calculated far-field directivity of the antenna tag at a predetermined UHF frequency of 915 MHz as a function of polar angle (θ) for a zero azimuthal angle (φ) where θ and φ have the conventional definition relative to the x-y-z axes of FIG. 1. The directivity on the lobes 1442 was 5.2 dBi. The 3 dB angular width 1443 was 82.6 degrees.

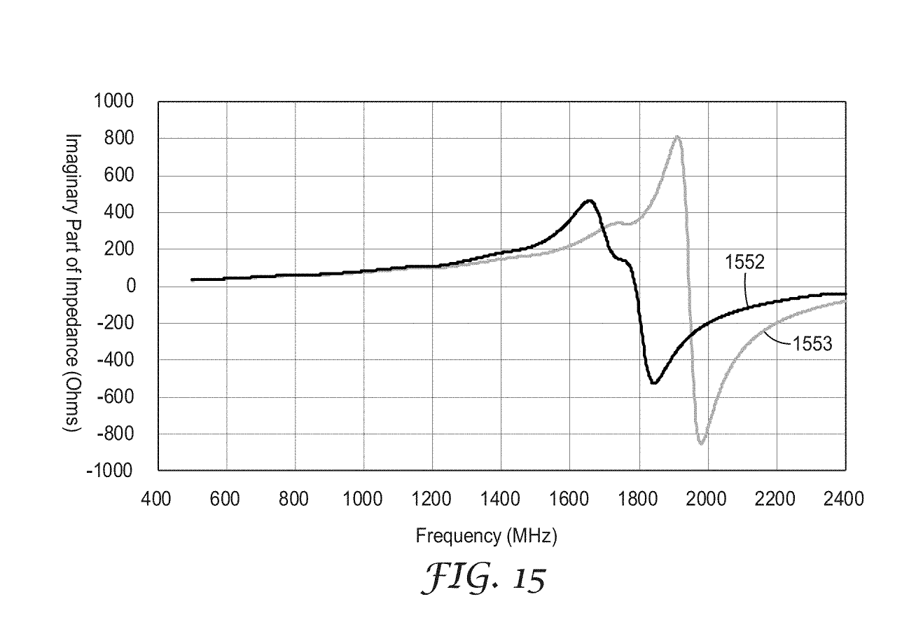

FIG. 15 is a plot of the calculated imaginary part (reactance) of the input impedance at the terminals when the antenna tag had a coating having a relative permittivity of 3.6 (curve 1552) and when there was no coating (curve 1553). At the predetermined frequency of 915 MHz, the reactance was 69.365 Ohms with the coating and 66.052 Ohms without the coating.

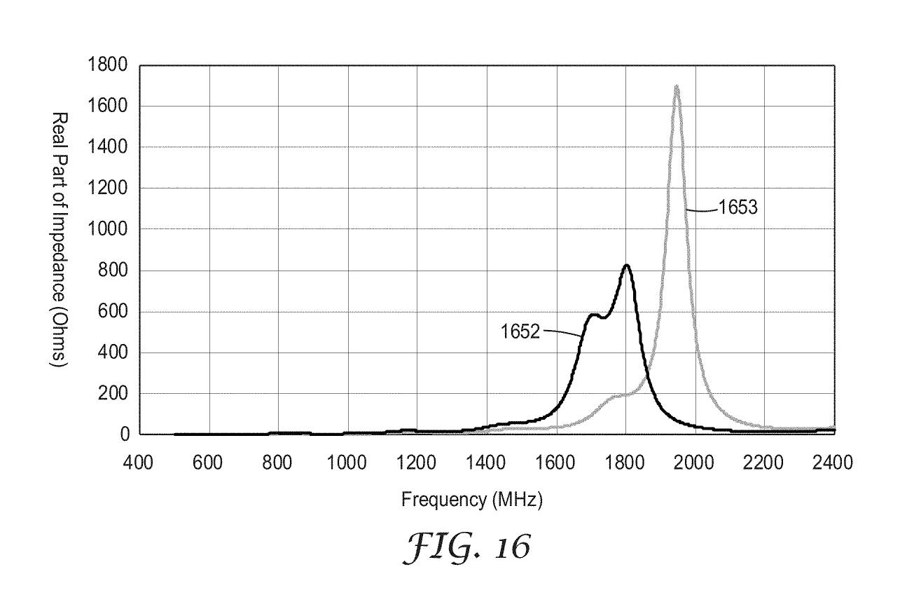

FIG. 16 is a plot of the calculated real part (resistance) of the input impedance at the terminals when the antenna tag had a coating having a relative permittivity of 3.6 (curve 1652) and when there was no coating (curve 1653). At the predetermined frequency of 915 MHz, the resistance was 5.586 Ohms with the coating and 4.958 Ohms without the coating.

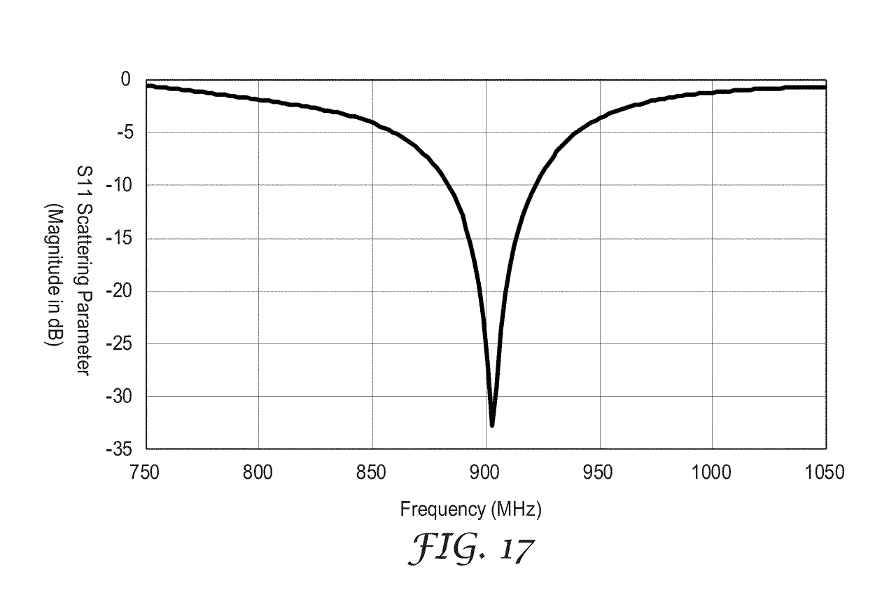

FIG. 17 is a plot of the calculated return loss (S11 scattering parameter) at the terminals when the antenna tag had a coating having a relative permittivity of 3.6. The return loss was less than −20 dB at the predetermined frequency of 915 MHz.

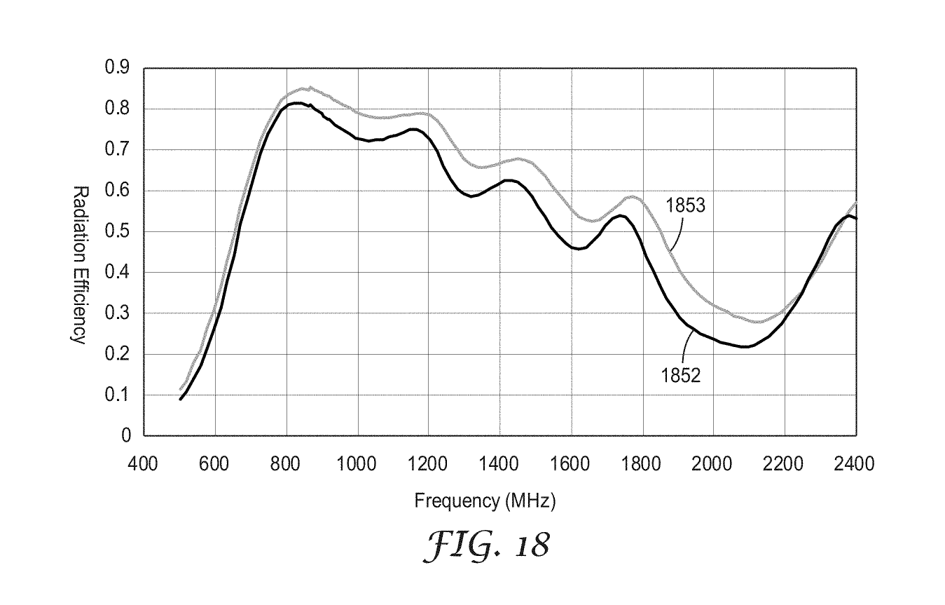

FIG. 18 is a plot of the calculated radiation efficiency when the antenna tag had a coating having a relative permittivity of 3.6 (curve 1852) and when there was no coating (curve 1853). At the predetermined frequency of 915 MHz, the radiation efficiency was 77.4% with the coating and 83% without the coating.

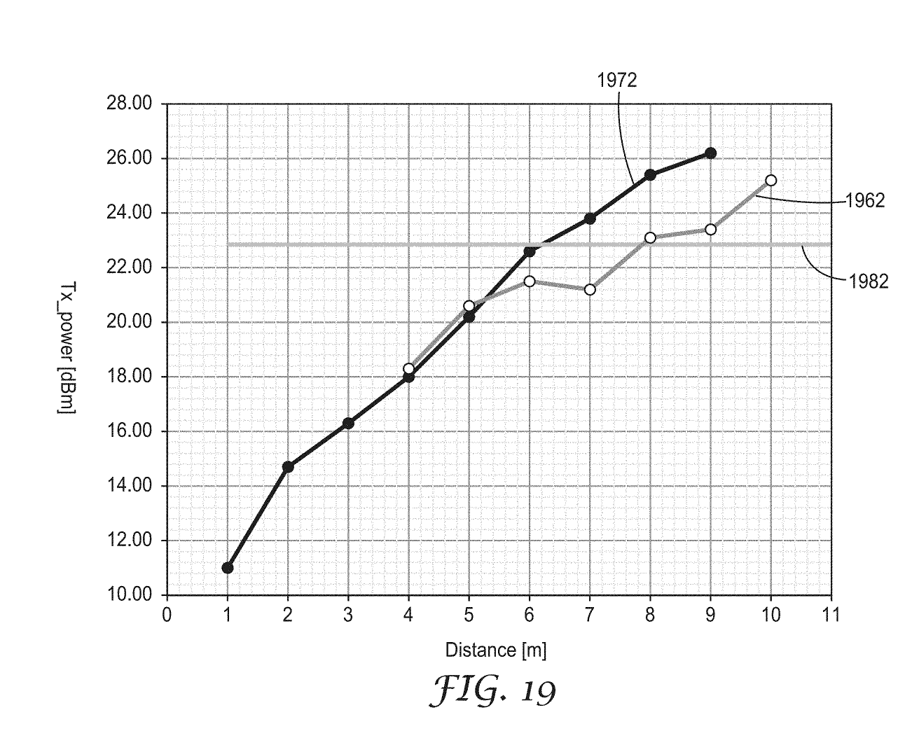

An antenna tag was fabricated by etching the pattern shown in FIGS. 1-3 in a copper layer of a copper-clad polyimide laminate having a 17 micrometer thick copper layer and a 25 micrometer thick polyimide layer. A coating having a relative permittivity of 3.6 at 915 MHz was applied to tag over the etched copper layer. The antenna tag was attached to a composite material (glass fibers in epoxy resin) coated with a wind blade finish paint. A reader with a high gain antenna (15 dBi) with vertical polarization was positioned at a distance from the antenna tag with the antenna tag facing the reader (the z-direction of FIG. 1 facing the reader with the polarization of the antenna along the x-direction of FIG. 1). The transmitted power at 915 MHz needed to achieve a maximum read range equal to the distance was determined. For comparison, a comparative antenna tag but having a conventional dogbone dipole antenna (similar to the antenna in the SMARTRAC SENSOR DOGBONE moisture level sensing inlay) was also tested. FIG. 19 is a plot of the transmitted power versus distance for the antenna tag (curve 1962) and the comparative antenna tag (curve 1972). The transmitted power 1982 corresponding to an EIRP of 36 dBm is indicated. For an EIRP of 36 dBm at 915 MHz, the antenna tag had a maximum read range of about 8 m while the comparative antenna tag had a maximum read range of less than 6.5 m.

### Example 2

An antenna tag as shown in FIGS. 4-6 was modeled. The dimensions shown in FIGS. 4-6 were L=280 mm, W1=101 mm, W2=125.5 mm, g=1 mm, s1=11 mm, s2=91.5 mm, s3=44 mm, s4=87 mm, s5=8.4 mm, and s6=11.4 mm.

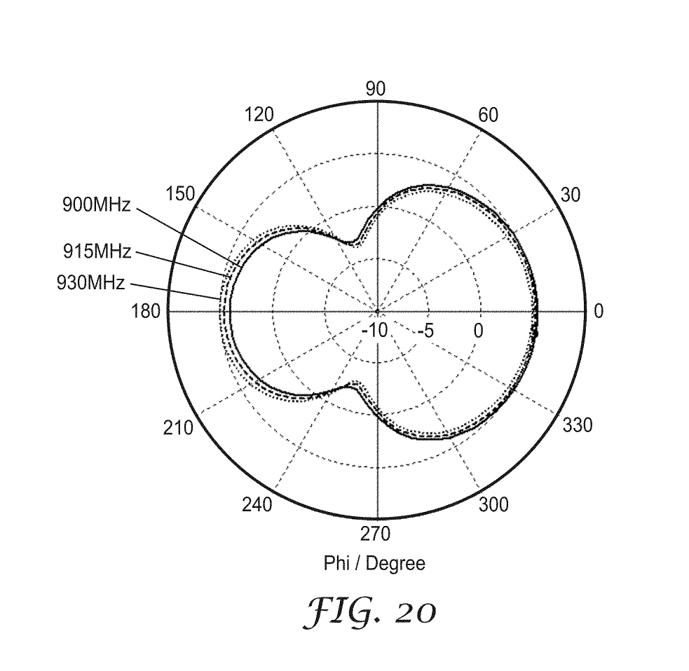

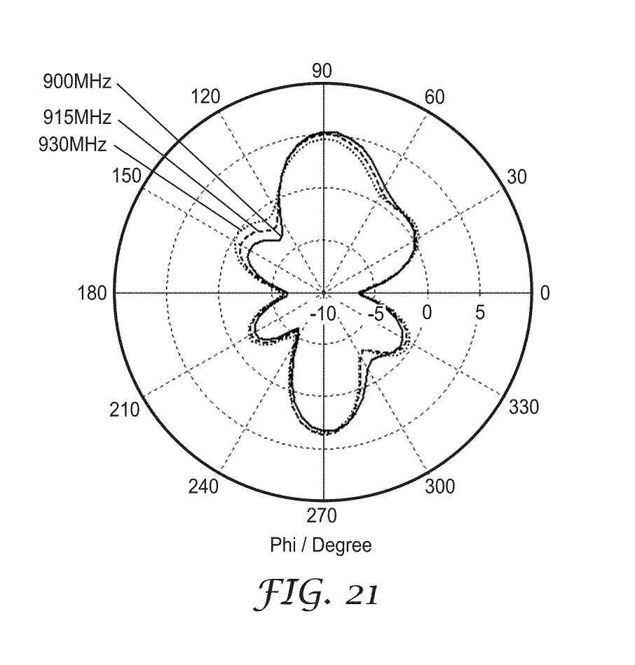

FIG. 20 is a plot of the calculated far-field directivity of the antenna tag at frequencies of 900 MHz, 915 MHz, and 930 MHz when disposed in a plane as in FIG. 4, for example. For Example 2, polar and azimuthal angles θ and φ are defined in the conventional way relative to the x′-y′-z′ axes of FIGS. 4-6. FIG. 20 shows the azimuthal dependence for θ=90 degrees. The maximum directivity was about 5.1 dBi. FIG. 21 is a plot of the calculated far-field directivity of the antenna tag at frequencies of 900 MHz, 915 MHz, and 930 MHz when disposed on a curved surface as illustrated in FIG. 8. FIG. 21 shows the polar dependence for φ=0 degrees. The maximum directivity was about 5.6 dBi.

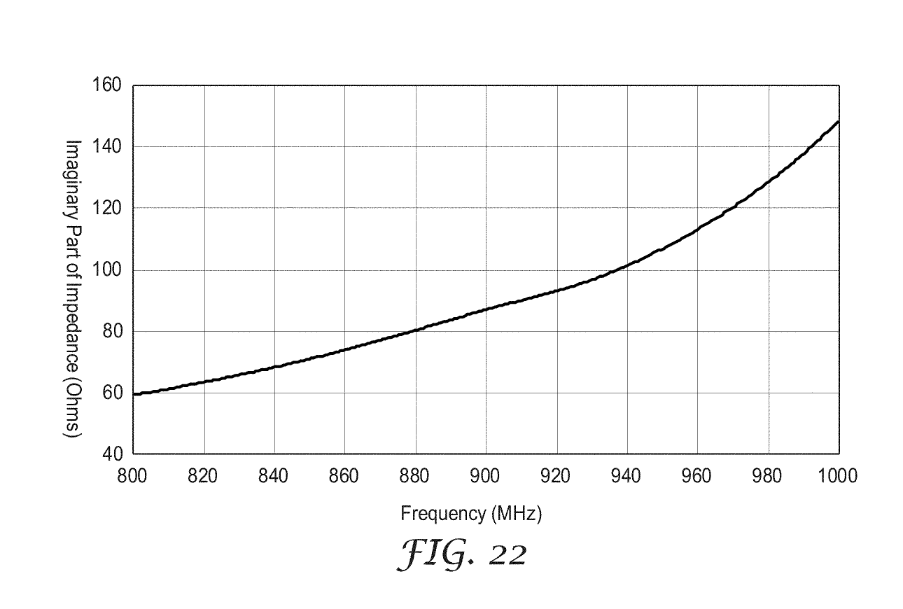

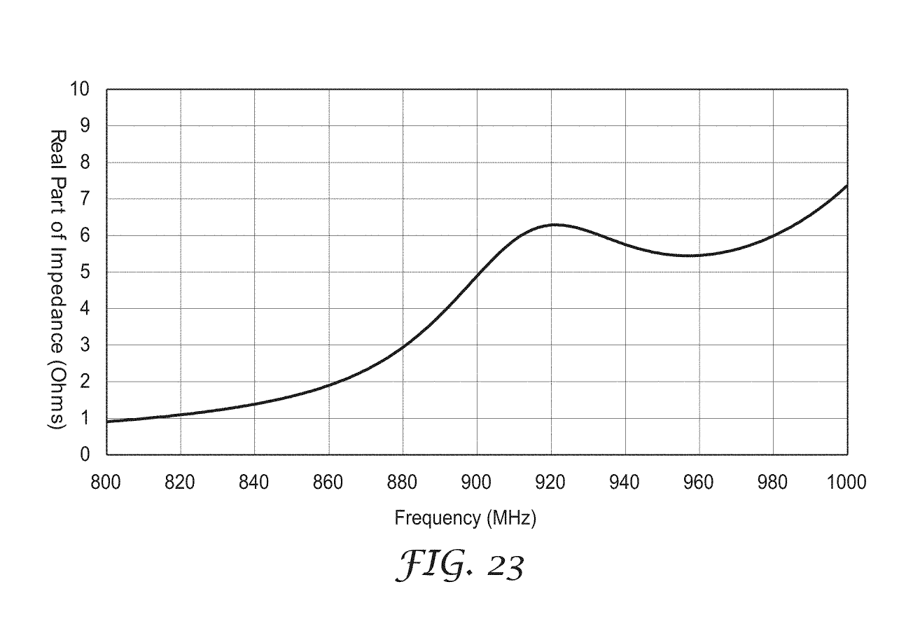

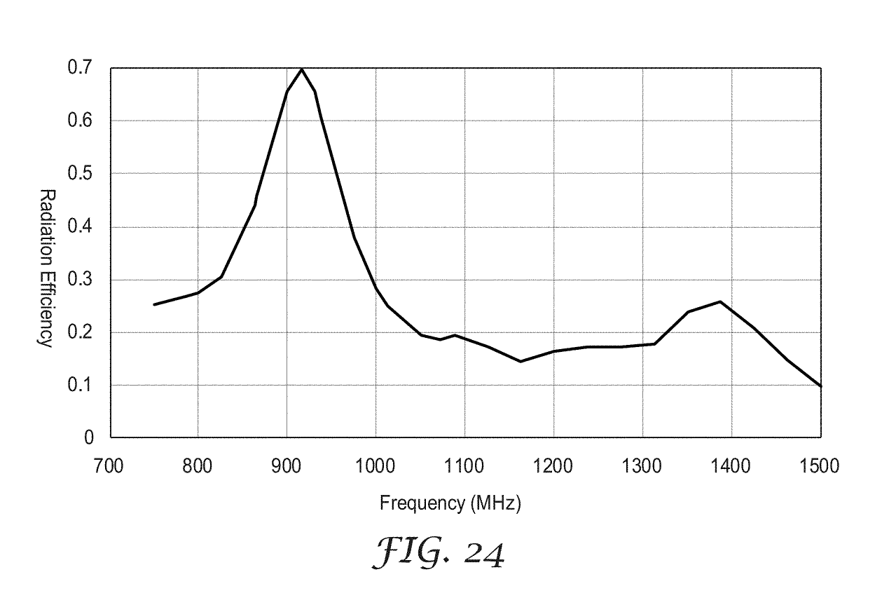

FIGS. 22-24 show results for when the antenna tag is disposed in a plane as in FIG. 4, for example. FIG. 22 is a plot of the calculated imaginary part (reactance) of the input impedance at the terminals versus frequency. FIG. 23 is a plot of the calculated real part (resistance) of the input impedance at the terminals versus frequency. FIG. 24 is a plot of the calculated radiation efficiency versus frequency.

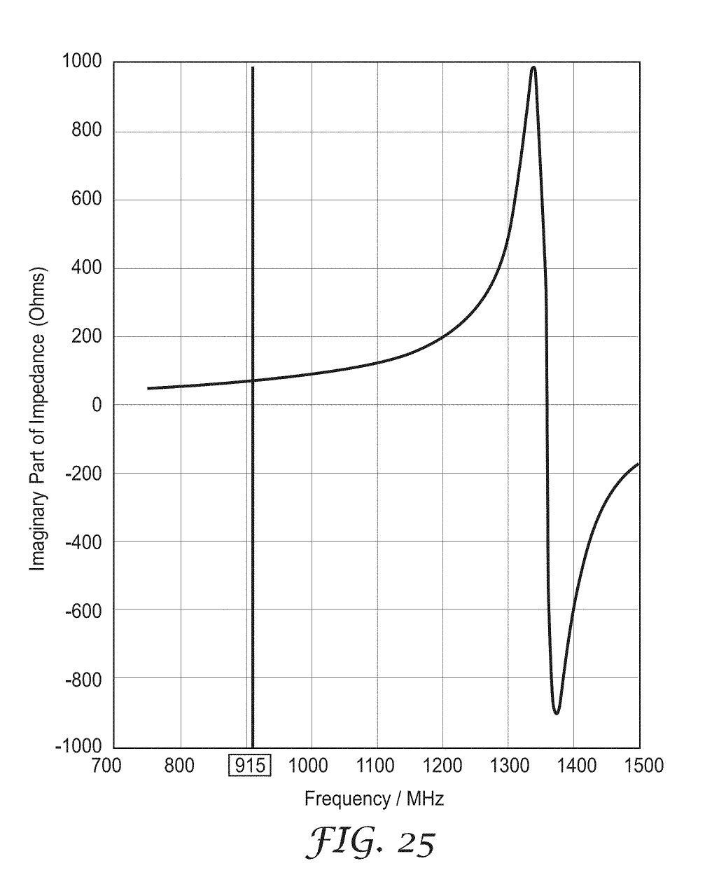

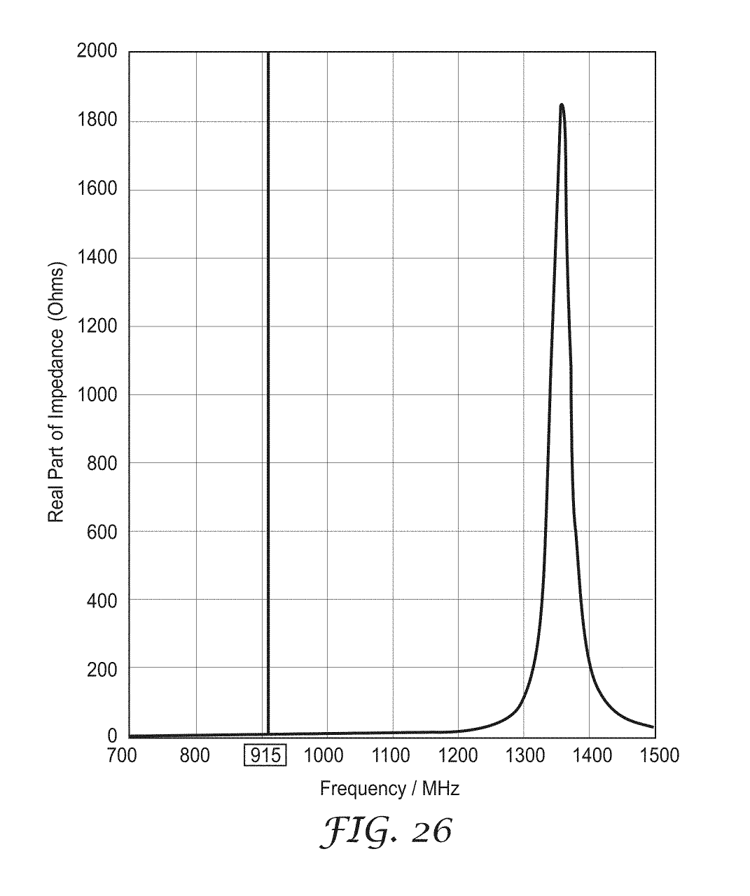

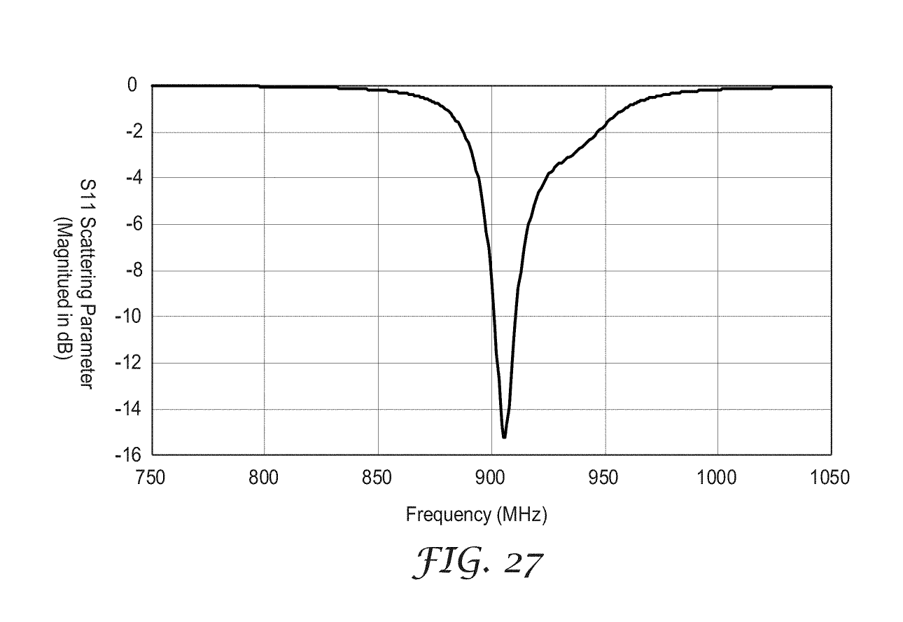

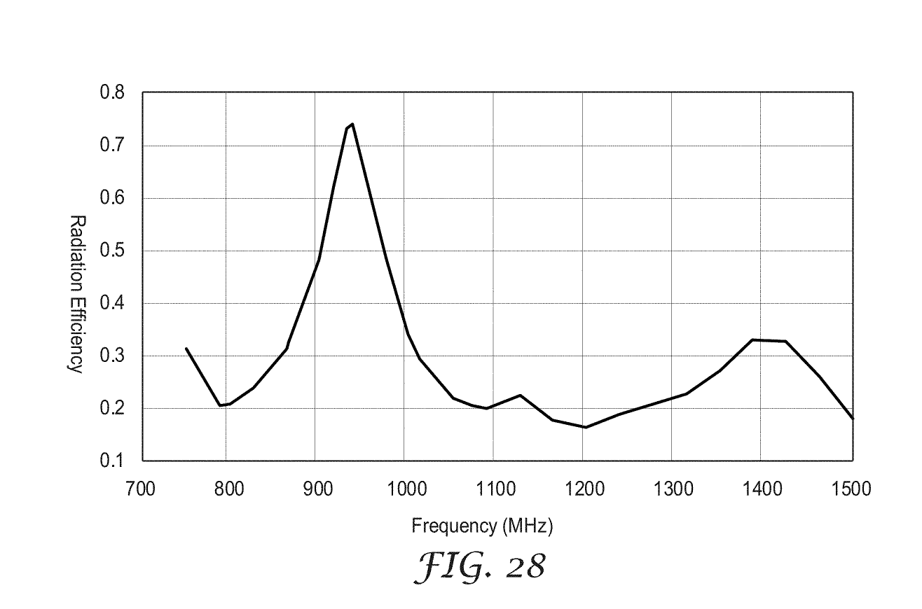

FIGS. 25-28 show results for when the antenna tag is disposed in curved as in FIG. 8. FIG. 25 is a plot of the calculated imaginary part (reactance) of the input impedance at the terminals versus frequency. The reactance at 915 MHz was 71.48 Ohms. FIG. 26 is a plot of the calculated real part (resistance) of the input impedance at the terminals versus frequency. The resistance at 915 MHz was 3.30 Ohms. FIG. 27 is a plot of the calculated return loss (S11 scattering parameter) at the terminals versus frequency. The return loss was less than −10 dB at the predetermined frequency of 915 MHz. FIG. 28 is a plot of the calculated radiation efficiency versus frequency.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. An ultra-high frequency (UHF) antenna tag comprising:
a sensor portion comprising terminals for attaching a chip having a chip impedance, the sensor portion responsive to a presence of a dielectric or magnetic material proximate the sensor portion;
an antenna portion comprising first and second elements electrically connected to the sensor portion, at least one of the first and second elements comprising at least one meandered portion, the antenna tag configured such that at a predetermined UHF frequency:
the antenna tag has an input impedance at the terminals substantially matched to the chip impedance;
the antenna tag has a directivity of at least 4 dBi in a predetermined direction; and
the antenna tag has a radiation efficiency of at least 60 percent.

2. The UHF antenna tag of claim 1, wherein when the antenna tag is disposed in a first plane, the antenna portion is symmetric under reflection about a second plane orthogonal to the first plane and symmetric under reflection about a third plane orthogonal to the first and second planes.

3. The UHF antenna tag of claim 1, wherein the sensor portion comprises a patterned conductor providing a capacitance at the terminals, the capacitance depending on an amount of water or ice present on the sensor portion.

4. The UHF antenna tag of claim 3, wherein the patterned conductor defines a gap pattern in the patterned conductor such that when the antenna tag is disposed in a first plane, the gap pattern is symmetric under rotations of 180 degrees about an axis perpendicular to the first plane.

5. The UHF antenna tag of claim 1, wherein the first element is disposed closer to the sensor portion and the second element is disposed farther from the sensor portion.

6. The UHF antenna tag of claim 5, wherein the first element comprises first and second portions and first and second linear connecting lines electrically connecting the respective first and second portions of the first element to the sensor portion, and wherein the second element comprises first and second portions and first and second meandered connecting lines electrically connecting the respective first and second portions of the second element to the sensor portion.

7. The UHF antenna tag of claim 1, wherein for an effective isotropic radiated power (EIRP) of 36 dBm at the predetermined UHF frequency, the UHF antenna tag has a maximum read range of at least 6 m.

8. A wind turbine comprising a rotor blade and the UHF antenna tag of claim 1 disposed on and conforming to a major surface of the rotor blade.

9. An ultra-high frequency (UHF) antenna tag comprising:
a sensor portion comprising terminals for attaching a chip having a chip impedance, the sensor portion responsive to a presence of a dielectric or magnetic material proximate the sensor portion;
an antenna portion comprising first and second meandered loop elements disposed on opposite sides of the sensor portion and electrically connected to the sensor portion such that the first meandered loop element and the sensor portion defines a first electrically closed loop and the second meandered loop element and the sensor portion defines a second electrically closed loop, the antenna tag configured such that at a predetermined UHF frequency:
the antenna tag has an input impedance at the terminals substantially matched to the chip impedance;
the antenna tag has a radiation efficiency of at least 60 percent; and
for an effective isotropic radiated power (EIRP) of 36 dBm, the UHF antenna tag has a maximum read range of at least 6 m.

10. The UHF antenna tag of claim 9 having a width and a length greater than the width, wherein the length is in a range of 0.55 to 0.69 times a predetermined wavelength, the predetermined wavelength being the speed of light in vacuum divided by the predetermined UHF frequency.

11. The UHF antenna tag of claim 9 having a directivity of at least 4 dBi in a direction normal to a plane of the antenna tag.

12. A wind turbine comprising a rotor blade and the UHF antenna tag of claim 9 disposed on and conforming to a major surface of the rotor blade.

13. An ultra-high frequency (UHF) antenna tag configured to be disposed on and conform to a curved surface, the UHF antenna tag comprising:
a sensor portion comprising terminals for attaching a chip having an impedance, the sensor portion responsive to a presence a dielectric or magnetic material proximate the sensor portion;
an antenna portion comprising a first dipole portion disposed closer to the sensor portion and a second dipole portion disposed farther from the sensor portion, the first and second dipole portions electrically connected to the sensor portion, the antenna tag configured such that at a predetermined UHF frequency when the antenna tag is disposed on and conforms to the curved surface:
the antenna tag has an input impedance at the terminals substantially matched to the impedance of the chip;
the antenna tag has a directivity of at least 3 dBi in a predetermined direction; and
the antenna tag has a radiation efficiency of at least 45 percent.

14. The UHF antenna tag of claim 13, wherein a first conductor length separates the first dipole portion from the terminals and a second conductor length separates the second dipole portion from the terminals, a difference between the second and first conductor lengths being selected such that the antenna tag has a largest directivity in the predetermined direction.

15. The UHF antenna tag of claim 13, wherein a fixed first conductor length separates the first dipole portion from the terminals and an adjustable second conductor length separates the second dipole portion from the terminals.

16. A wind turbine comprising the UHF antenna tag of claim 13 disposed on and conforming to a curved major surface of a rotor blade.

17. The wind turbine of claim 16 further comprising a reader antenna disposed to communicate with the UHF antenna tag, wherein when the UHF antenna tag is closest to the reader antenna, the predetermined direction is substantially along a direction from the UHF antenna tag to the reader antenna.

18. A wind turbine comprising one or more rotor blades, each rotor blade comprising a leading edge, wherein for at least one rotor blade, at least one ultra-high frequency (UHF) antenna tag is disposed on and conforms to a curved major surface of the rotor blade, each antenna tag comprising:
a sensor portion comprising terminals, the sensor portion disposed on the leading edge of the rotor blade, the sensor portion responsive to a presence a dielectric or magnetic material proximate the sensor portion;
a chip electrically connected to the terminals;
an antenna portion comprising a first dipole portion disposed closer to the sensor portion and a second dipole portion disposed farther from the sensor portion, the first and second dipole portions electrically connected to the sensor portion, a first conductor length separating the first dipole portion from the sensor portion, a second conductor length separating the second dipole portion from the sensor portion, the wind turbine further comprising one or more reader antennas disposed proximate the at least one antenna tag, wherein for each antenna tag and a reader antenna in the one or more reader antennas disposed to communicate with the antenna tag, a difference between the second and first conductor lengths is selected such that when the antenna tag is closest to the reader antenna, the antenna tag has a directivity of at least 3 dBi in a direction toward the reader antenna.

19. The wind turbine of claim 18, wherein a plurality of the antenna tags is disposed on and conforms to the curved major surface of each rotor blade.

20. The wind turbine of claim 19, wherein the one or more reader antennas comprises a plurality of reader antennas and for each rotor blade, the plurality of antenna tags disposed on and conforming to the curved major surface of the rotor blade is in one-to-one correspondence with the plurality of reader antennas.
